(19) United States
(12) Patent Application Publication
(10) Pub. No.: US 2025/0071998 A1
(43) Pub. Date: Feb. 27, 2025

(54) THREE-DIMENSIONAL MEMORY DEVICE WITH SOURCE CONTACT LAYER HAVING HORIZONTALLY AND VERTICALLY EXTENDING PORTIONS AND METHODS OF FORMING THE SAME

(71) Applicant: WESTERN DIGITAL TECHNOLOGIES, INC.,, SAN JOSE, CA (US)

(72) Inventors: Masanori TSUTSUMI, Yokkaichi (JP); Hiroyuki TANAKA, Yokkaichi (JP); Ryota SUZUKI, Yokkaichi (JP); Tomoyuki OBU, Yokkaichi (JP)

(21) Appl. No.: 18/452,737

(22) Filed: Aug. 21, 2023

(51) Int. Cl. H10B 43/35; G11C 16/04; H01L 23/522; H01L 23/528; H10B 41/10; H10B 41/27; H10B 41/35; H10B 43/10; H10B 43/27

(52) U.S. Cl. CPC H10B 43/35; G11C 16/0483; H01L 23/5226; H01L 23/5283; H10B 41/10; H10B 41/27; H10B 41/35; H10B 43/10; H10B 43/27

(57) ABSTRACT

A memory device includes source-level material layers containing a lower source-level semiconductor layer, a source contact layer, and an upper source-level semiconductor layer, an alternating stack of insulating layers and electrically conductive layers located over the source-level material layers, a memory opening vertically extending through the alternating stack and into an upper portion of the source-level material layers, and a memory opening fill structure located in the memory opening and including a memory film and a vertical semiconductor channel. The source contact layer includes a horizontally-extending portion and a vertically-extending portion having a greater vertical extent than the horizontally-extending portion, having an inner cylindrical sidewall contacting a bottom portion of the vertical semiconductor channel, and contacting a bottommost insulating layer within the alternating stack.

### FIELD

The present disclosure relates generally to the field of semiconductor devices, and particularly to a three-dimensional semiconductor device with a source contact layer having both horizontally and vertically extending portions and methods of forming the same.

### BACKGROUND

Three-dimensional vertical NAND strings having one bit per cell are disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device is provided, which comprises: source-level material layers comprising a stack including a lower source-level semiconductor layer, a source contact layer, and an upper source-level semiconductor layer; an alternating stack of insulating layers and electrically conductive layers located over the source-level material layers; a memory opening vertically extending through the alternating stack and into an upper portion of the source-level material layers; and a memory opening fill structure located in the memory opening and comprising a memory film and a vertical semiconductor channel. The source contact layer comprises a horizontally-extending portion and a vertically-extending portion having a greater vertical extent than the horizontally-extending portion, having an inner cylindrical sidewall contacting a bottom portion of the vertical semiconductor channel, and contacting a bottommost insulating layer within the alternating stack.

According to another aspect of the present disclosure, a method of forming a memory device comprises: forming in-process source-level material layers comprising a stack including a lower source-level semiconductor layer, a source-level sacrificial layer, and an upper source-level semiconductor layer; forming an alternating stack of insulating layers and sacrificial material layers located over the in-process source-level material layers; forming a memory opening vertically extending through the alternating stack and an upper portion of the in-process source-level material layers, wherein the memory opening comprises a first annular cavity located at a level of the upper source-level semiconductor layer and undercutting the alternating stack; forming a first annular cavity fill structure in the first annular cavity; forming a memory opening fill structure in a volume of the memory opening other than a volume of the first annular cavity, wherein the memory opening fill structure comprises a memory film and a vertical semiconductor channel; replacing at least the source-level sacrificial layer and the first annular cavity fill structure with at least one replacement material layer comprising a source contact layer, wherein the source contact layer is formed directly on a lower portion of an outer sidewall of the vertical semiconductor channel; and replacing the sacrificial material layers with electrically conductive layers.

### BRIEF DESCRIPTION OF THE DRAWINGS

FIG. 1 is a schematic vertical cross-sectional view of a first exemplary structure after formation of a backside insulating layer and in-process source-level material layers according to a first embodiment of the present disclosure.

FIG. 2 is a schematic vertical cross-sectional view of the first exemplary structure after formation of an alternating stack of insulating layers and sacrificial material layers according to the first embodiment of the present disclosure.

FIG. 3 is a schematic vertical cross-sectional view of the first exemplary structure after formation of stepped surfaces and a retro-stepped dielectric material portion according to the first embodiment of the present disclosure.

FIG. 4A is a schematic vertical cross-sectional view of the first exemplary structure after forming memory openings and support openings according to the first embodiment of the present disclosure.

FIG. 4B is a top-down view of the first exemplary structure of FIG. 4A. The hinged vertical plane A-A′ is the cut plane of the vertical cross-sectional view of FIG. 4A.

FIG. 5 is a schematic vertical cross-sectional view of the first exemplary structure after formation of sacrificial memory opening fill structures according to the first embodiment of the present disclosure.

FIG. 6 is a schematic vertical cross-sectional view of the first exemplary structure after formation of support pillar structures according to the first embodiment of the present disclosure.

FIG. 7 is a schematic vertical cross-sectional view of the first exemplary structure after removal of the sacrificial memory opening fill structures according to the first embodiment of the present disclosure.

FIGS. 8A-8H are sequential vertical cross-sectional views of a memory opening during formation of a memory opening fill structure according to the first embodiment of the present disclosure.

FIG. 9A is a vertical cross-sectional view of the first exemplary structure after formation of memory opening fill structures according to the first embodiment of the present disclosure.

FIG. 9B is a top-down view of the first exemplary structure of FIG. 9A. The hinged vertical plane A-A′ is the cut plane of the vertical cross-sectional view of FIG. 9A.

FIG. 10A is a vertical cross-sectional view of the first exemplary structure after formation of lateral isolation trenches according to the first embodiment of the present disclosure.

FIG. 10B is a top-down view of the first exemplary structure of FIG. 10A. The hinged vertical plane A-A′ is the cut plane of the vertical cross-sectional view of FIG. 10A.

FIG. 11 is a vertical cross-sectional view of the first exemplary structure after formation of sacrificial spacer layers according to the first embodiment of the present disclosure.

FIGS. 12A and 12B are vertical cross-sectional view of the first exemplary structure after removal of horizontally-extending portions of the sacrificial spacer layers and a vertical portion of the inner sacrificial spacer layer according to the first embodiment of the present disclosure.

FIG. 13 is a vertical cross-sectional view of the first exemplary structure after formation of sacrificial semiconductor oxide liners according to the first embodiment of the present disclosure.

FIG. 14A is a vertical cross-sectional view of the first exemplary structure after formation of a source cavity according to the first embodiment of the present disclosure.

FIG. 14B is a magnified view of a region of the first exemplary structure of FIG. 14A.

FIGS. 15A-15H are sequential vertical cross-sectional views of a region of the first exemplary structure during replacement of a source-level sacrificial layer with a source contact layer and a source-level dielectric fill layer and replacement of the sacrificial material layers with electrically conductive layers according to the first embodiment of the present disclosure.

FIG. 16A is a vertical cross-sectional view of the first exemplary structure after formation of lateral isolation trench fill structures and contact via structures according to the first embodiment of the present disclosure.

FIG. 16B is a magnified view of a region of the first exemplary structure of FIG. 16A.

FIG. 17A is a vertical cross-sectional view of the first exemplary structure after formation of various contact via structures according to the first embodiment of the present disclosure.

FIG. 17B is a top-down view of the first exemplary structure of FIG. 17A. The vertical plane A-A′ is the cut plane of the vertical cross-sectional view of FIG. 17A.

FIG. 18 is a vertical cross-sectional view of the first exemplary structure after formation of a memory die according to the first embodiment of the present disclosure.

FIG. 19 is a vertical cross-sectional view of a logic die according to the first embodiment of the present disclosure.

FIG. 20 is a vertical cross-sectional view of the first exemplary structure after formation of a bonded assembly of the memory die and the logic die according to the first embodiment of the present disclosure.

FIG. 21 is a schematic vertical cross-sectional view of a second exemplary structure after formation of in-process source-level material layers an insulating liner according to a second embodiment of the present disclosure.

FIG. 22A is a schematic vertical cross-sectional view of the second exemplary structure after formation of discrete source-level openings according to the second embodiment of the present disclosure.

FIG. 22B is a top-down view of the second exemplary structure of FIG. 22A. The hinged vertical cross-sectional plane A-A′ is the cut plane of the vertical cross-sectional view of FIG. 22A.

FIGS. 23A-23C are vertical cross-sectional views around a discrete source-level opening during formation of a sacrificial pedestal structure according to the second embodiment of the present disclosure.

FIG. 24 is a schematic vertical cross-sectional view of the second exemplary structure after formation of an alternating stack of insulating layers and sacrificial material layers according to the second embodiment of the present disclosure.

FIG. 25 is a schematic vertical cross-sectional view of the second exemplary structure after formation of stepped surfaces and a retro-stepped dielectric material portion, cylindrical memory cavities, and support openings according to the second embodiment of the present disclosure.

FIG. 26 is a schematic vertical cross-sectional view of the second exemplary structure after formation of sacrificial memory cavity fill structures according to the second embodiment of the present disclosure.

FIG. 27 is a schematic vertical cross-sectional view of the second exemplary structure after formation of support pillar structures according to the second embodiment of the present disclosure.

FIG. 28 is a schematic vertical cross-sectional view of the second exemplary structure after removal of the sacrificial memory cavity fill structures and sacrificial pedestal structures according to the second embodiment of the present disclosure.

FIGS. 29A and 29B are sequential vertical cross-sectional views of a memory opening during formation of a memory opening fill structure according to the second embodiment of the present disclosure.

FIG. 30 is a vertical cross-sectional view of the second exemplary structure after formation of a bonded assembly of the memory die and the logic die according to the second embodiment of the present disclosure.

FIG. 31 is a vertical cross-sectional view of a region of a third exemplary structure after formation of a source cavity according to a third embodiment of the present disclosure.

FIG. 32 is a vertical cross-sectional view of a region of the third exemplary structure after removal of sacrificial recess fill structures according to the third embodiment of the present disclosure.

### DETAILED DESCRIPTION

As discussed above, the present disclosure is directed to a three-dimensional semiconductor device with a source contact layer having both horizontally and vertically extending portions and methods of forming the same, the various aspects of which are described below.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are employed merely to identify similar elements, and different ordinals may be employed across the specification and the claims of the instant disclosure. The term “at least one” element refers to all possibilities including the possibility of a single clement and the possibility of multiple elements.

The same reference numerals refer to the same element or similar element. Unless otherwise indicated, elements having the same reference numerals are presumed to have the same composition and the same function. Unless otherwise indicated, a “contact” between elements refers to a direct contact between elements that provides an edge or a surface shared by the elements. If two or more elements are not in direct contact with each other or among one another, the two elements are “disjoined from” each other or “disjoined among” one another. As used herein, an element located “on” a second element can be located on the exterior side of a surface of the second element or on the interior side of the second element. As used herein, an element is located “directly on” a second element if there exist a physical contact between a surface of the element and a surface of the second element. As used herein, an clement is “electrically connected to” a second element if there exists a conductive path consisting of at least one conductive material between the element and the second element. As used herein, a “prototype” structure or an “in-process” structure refers to a transient structure that is subsequently modified in the shape or composition of at least one component therein.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

Generally, a semiconductor die, or a semiconductor package, can include a memory chip. Each semiconductor package contains one or more dies (for example one, two, or four). The die is the smallest unit that can independently execute commands or report status. Each die contains one or more planes (typically one or two). Identical, concurrent operations can take place on each plane, although with some restrictions. Each plane contains a number of blocks, which are the smallest unit that can be erased in a single erase operation. Each block contains a number of pages, which are the smallest unit that can be programmed, i.e., a smallest unit on which a read operation can be performed.

As used herein, a “semiconducting material” refers to a material having electrical conductivity in the range from 1.0×10⁻⁵ S/m to 1.0×10⁻⁵ S/m. As used herein, a “semiconductor material” refers to a material having electrical conductivity in the range from 1.0×10⁻⁵ S/m to 1.0 S/m in the absence of electrical dopants therein, and is capable of producing a doped material having electrical conductivity in a range from 1.0 S/m to 1.0×10⁷ S/m upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/m. As used herein, an “insulator material” or a “dielectric material” refers to a material having electrical conductivity less than 1.0×10⁻⁵ S/m. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to provide electrical conductivity greater than 1.0×10⁵ S/m. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁵ S/m to 1.0×10⁷ S/m. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material may be semiconducting or conductive depending on the atomic concentration of electrical dopants therein. As used herein, a “metallic material” refers to a conductive material including at least one metallic element therein. All measurements for electrical conductivities are made in the standard condition.

Generally, a semiconductor package (or a “package”) refers to a unit semiconductor device that may be attached to a circuit board through a set of pins or solder balls. A semiconductor package may include a semiconductor chip (or a “chip”) or a plurality of semiconductor chips that are bonded throughout, for example, by flip-chip bonding or another chip-to-chip bonding. A package or a chip may include a single semiconductor die (or a “die”) or a plurality of semiconductor dies. A die is the smallest unit that may independently execute external commands or report status. Typically, a package or a chip with multiple dies is capable of simultaneously executing as many a number of external commands as the total number of dies therein. Each die includes one or more planes. Identical concurrent operations may be executed in each plane within a same die, although there may be some restrictions. In case a die is a memory die, i.e., a die including memory elements, concurrent read operations, concurrent write operations, or concurrent erase operations may be performed in each plane within a same memory die. In a memory die, each plane contains a number of memory blocks (or “blocks”), which are the smallest unit that may be erased by in a single erase operation. Each memory block contains a number of pages, which are the smallest units that may be selected for programming. A page is also the smallest unit that may be selected to a read operation.

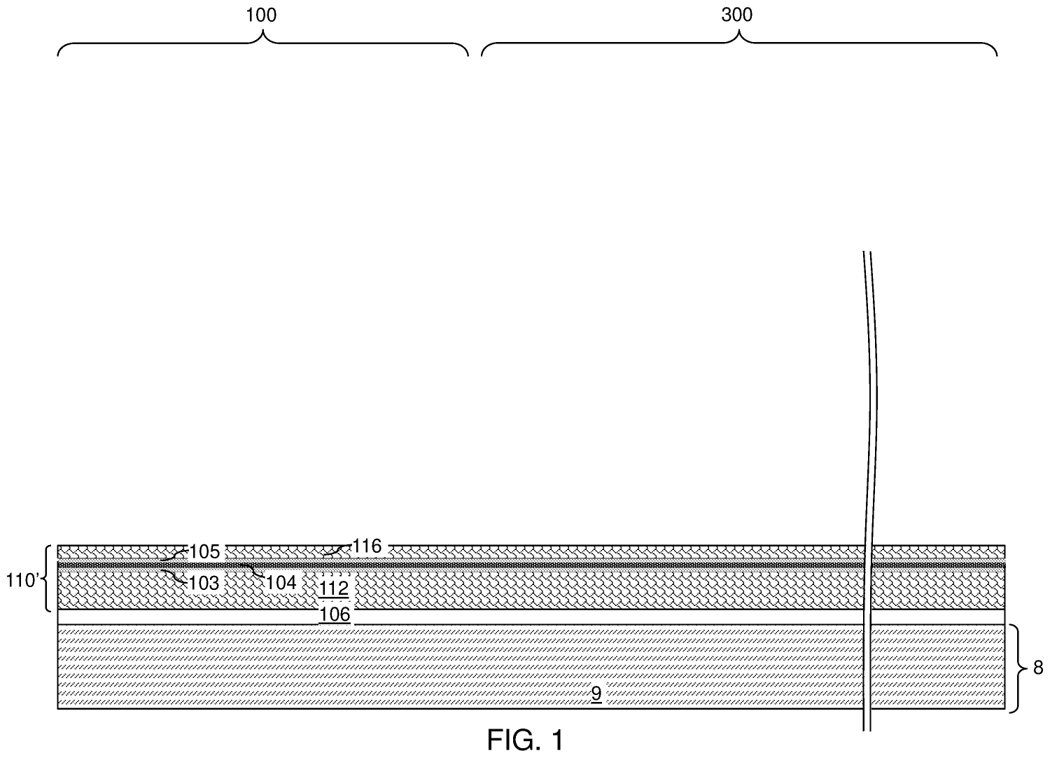

Referring to FIG. 1, a first exemplary structure according to an embodiment of the present disclosure includes a substrate 8. The substrate 8 may comprise a semiconductor material (e.g., a silicon wafer), an insulating material, a conductive material, or a combination thereof. The substrate 8 comprises a material that can provide structural support to material portions that are subsequently formed thereupon. The substrate 8 comprises a substrate material layer 9 at least at an upper portion thereof. In one embodiment, the substrate material layer 9 may be a semiconductor material layer, such as a silicon layer or a doped well in a silicon wafer.

A backside insulating layer 106 can be formed on a top surface of the substrate 8 (e.g., on the substrate material layer 9). In one embodiment, the backside insulating layer 106 comprises a dielectric material such as undoped silicate glass (i.e., silicon oxide), a doped silicate glass, or silicon nitride. The thickness of the backside insulating layer 106 may be in a range from 50 nm to 600 nm, such as from 100 nm to 300 nm, although lesser and greater thicknesses may also be employed.

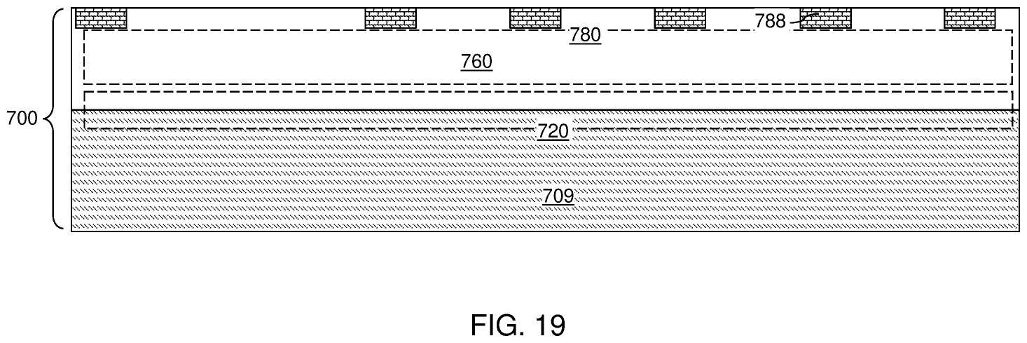

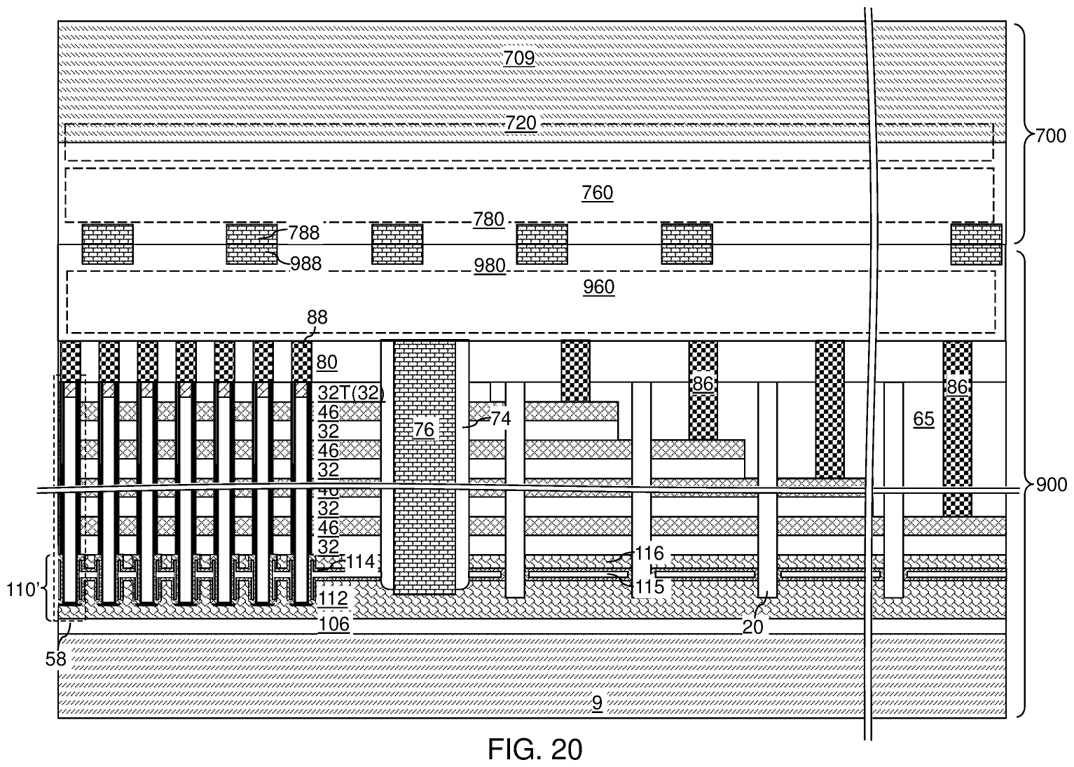

Optionally, a peripheral circuit may be formed in the substrate material layer 9 below the backside insulating layer 106. According to an aspect of the present disclosure, the peripheral circuit can be configured to control operation of the memory array to be formed above the backside insulating layer 106. For example, the peripheral circuit may comprise word line driver regions, bit line driver regions, sense amplifier regions, input/output buffer regions, etc. Alternatively, the peripheral circuit formation below the backside insulating layer 106 may be omitted, and the peripheral circuit may be formed on a separate logic die which is then bonded to the memory array, as will be described in more detail below with respect to FIGS. 19-20.

In-process source-level material layers 110′ can be formed over the backside insulating layer 106. The in-process source-level material layers 110′ may include various layers that are subsequently modified to form source-level material layers (e.g., buried source line). The source-level material layers, upon formation, include a source contact layer that functions as a common source region for vertical NAND strings of a three-dimensional memory device. In one embodiment, the in-process source-level material layers 110′ may include, from bottom to top, a lower source-level semiconductor layer 112, an optional lower sacrificial liner 103, a source-level sacrificial layer 104, an optional upper sacrificial liner 105, and an upper source-level semiconductor layer 116.

The lower source-level semiconductor layer 112 and the upper source-level semiconductor layer 116 may include a doped semiconductor material such as doped polysilicon or doped amorphous silicon. The conductivity type of the lower source-level semiconductor layer 112 and the upper source-level semiconductor layer 116 may be the opposite of the conductivity of vertical semiconductor channels to be subsequently formed. For example, if the vertical semiconductor channels to be subsequently formed have a doping of a first conductivity type, the lower source-level semiconductor layer 112 and the upper source-level semiconductor layer 116 have a doping of a second conductivity type that is the opposite of the first conductivity type. In one embodiment, the lower source-level semiconductor layer 112 and the upper source-level semiconductor layer 116 may comprise n-type, phosphorus doped polysilicon. The thickness of each of the lower source-level semiconductor layer 112 and the upper source-level semiconductor layer 116 may be in a range from 10 nm to 300 nm, such as from 100 nm to 150 nm, although lesser and greater thicknesses may also be used.

The source-level sacrificial layer 104 includes a sacrificial material that may be removed selective to the lower sacrificial liner (or selective to the lower source-level semiconductor layer 112) and the upper sacrificial liner (or selective to the upper source-level semiconductor layer 116). In one embodiment, the source-level sacrificial layer 104 may include silicon nitride or a semiconductor material, such as undoped amorphous silicon. The thickness of the source-level sacrificial layer 104 may be in a range from 10 nm to 100 nm, such as from 20 nm to 50 nm, although lesser and greater thicknesses may also be used. The lower sacrificial liner 103 (if present) and the upper sacrificial liner 105 (if present) include materials that may function as an etch stop material during removal of the source-level sacrificial layer 104. For example, the lower sacrificial liner 103 and the upper sacrificial liner 105 may include silicon oxide, silicon nitride, and/or a dielectric metal oxide. In one embodiment, the source-level sacrificial layer 104 comprises a silicon nitride layer, and each of the lower sacrificial liner 103 and the upper sacrificial liner 105 comprise silicon oxide layers having a thickness in a range from 2 nm to 30 nm, although lesser and greater thicknesses may also be used.

The first exemplary structure comprises a memory array region 100 in which a three-dimensional array of memory elements is to be subsequently formed, and a contact region 300 in which layer contact via structures contacting word lines are to be subsequently formed.

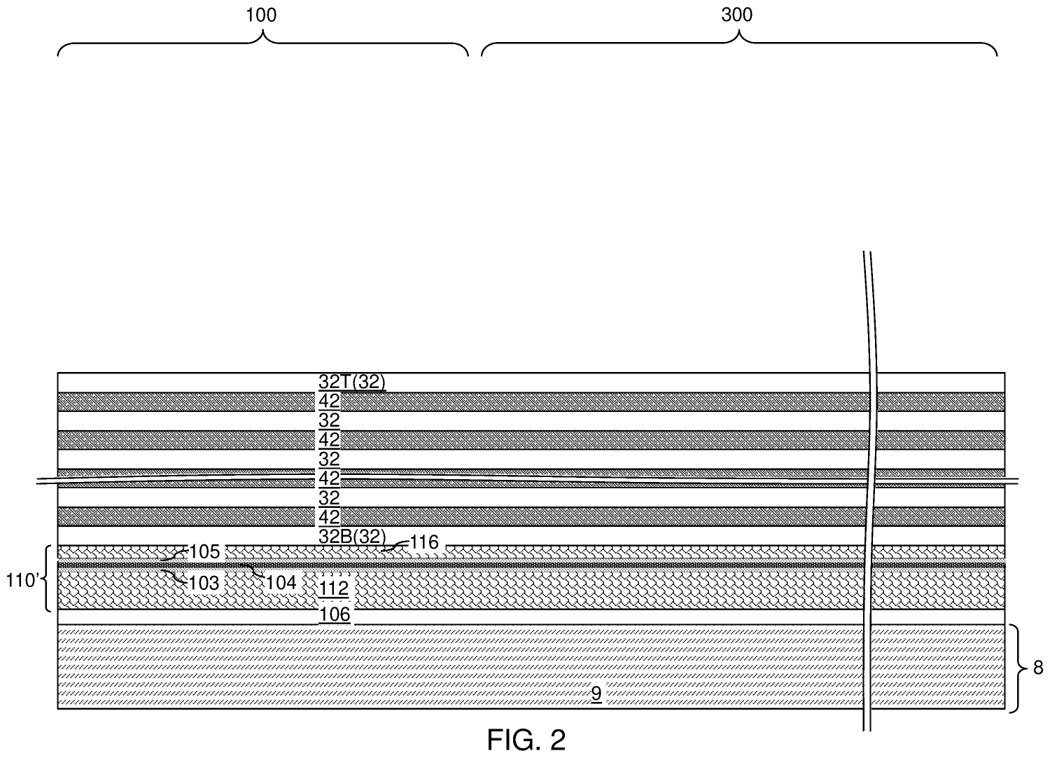

Referring to FIG. 2, an alternating stack of first material layers and second material layers can be formed over the in-process source-level material layers 110′. The first material layers may be insulating layers, and the second material layers may be spacer material layers. In one embodiment, the spacer material layers may comprise sacrificial material layers 42. In this case, an alternating stack (32, 42) of insulating layers 32 and sacrificial material layers 42 can be formed over the in-process source-level material layers 110′. The insulating layers 32 comprise an insulating material such as undoped silicate glass or a doped silicate glass, and the sacrificial material layers 42 comprise a sacrificial material, such as silicon nitride or a silicon-germanium alloy. In one embodiment, the insulating layers 32 (i.e., the first material layers) may comprise silicon oxide layers, and the sacrificial material layers 42 (i.e., the second material layers) may comprise silicon nitride layers. The alternating stack (32, 42) may comprise multiple repetitions of a unit layer stack including an insulating layer 32 and a sacrificial material layer 42. The total number of repetitions of the unit layer stack within the alternating stack (32, 42) may be, for example, in a range from 8 to 1,024, such as from 32 to 256, although lesser and greater number of repetitions may also be employed. The topmost one of the insulating layers 32 is hereafter referred to as a topmost insulating layer 32T. The bottommost one of the insulating layers 32 is an insulating layer 32 that is most proximal to the substrate 8 is herein referred to as a bottommost insulating layer 32B.

Each of the insulating layers 32 other than the topmost insulating layer 32T may have a thickness in a range from 20 nm to 100 nm, such as from 30 nm to 60 nm, although lesser and greater thicknesses may also be employed. Each of the sacrificial material layers 42 may have a thickness in a range from 20 nm to 100 nm, such as from 30 nm to 60 nm, although lesser and greater thicknesses may also be employed. In one embodiment, the topmost insulating layer 32T may have a thickness of about one half of the thickness of other insulating layers 32.

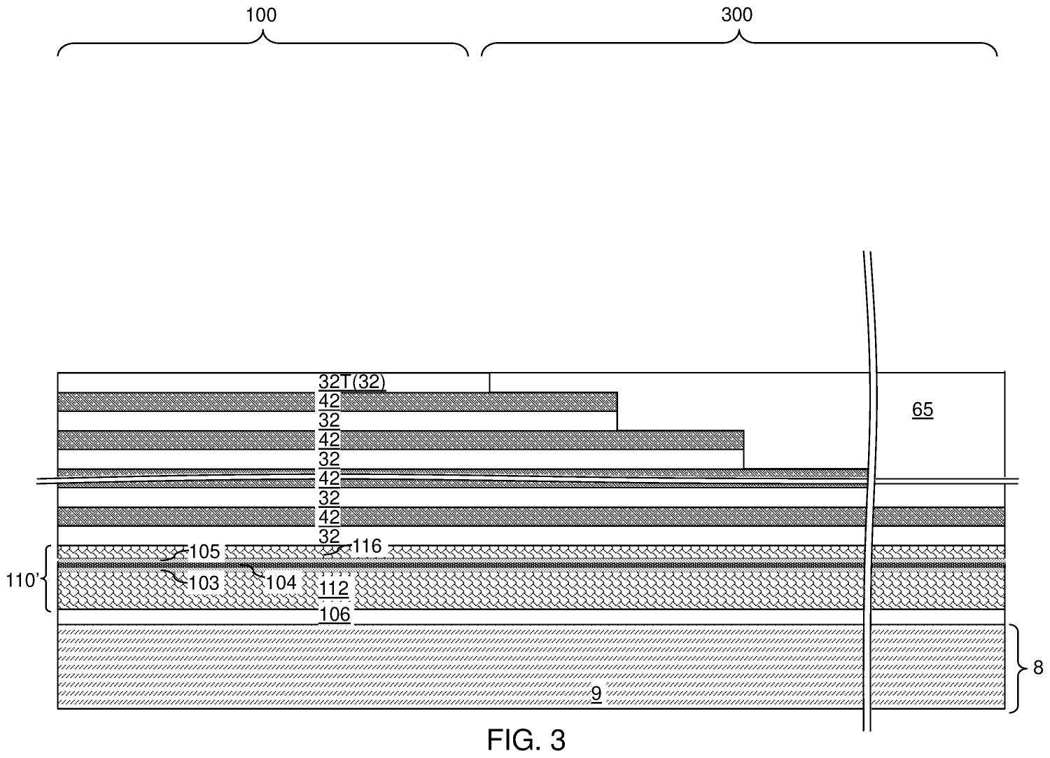

Referring to FIG. 3, stepped surfaces are formed in the contact region 300. As used herein, “stepped surfaces” refer to a set of surfaces that include at least two horizontal surfaces and at least two vertical surfaces such that each horizontal surface is adjoined to a first vertical surface that extends upward from a first edge of the horizontal surface, and is adjoined to a second vertical surface that extends downward from a second edge of the horizontal surface. A stepped cavity is formed within the volume from which portions of the alternating stack (32, 42) are removed through formation of the stepped surfaces. A “stepped cavity” refers to a cavity having stepped surfaces.

The stepped cavity can have various stepped surfaces such that the horizontal cross-sectional shape of the stepped cavity changes in steps as a function of the vertical distance from the top surface of the in-process source-level material layers 110′. In one embodiment, the stepped cavity can be formed by repetitively performing a set of processing steps. The set of processing steps can include, for example, an etch process of a first type that vertically increases the depth of a cavity by one or more levels, and an etch process of a second type that laterally expands the area to be vertically etched in a subsequent etch process of the first type. As used herein, a “level” of a structure including alternating plurality is defined as the relative position of a pair of a first material layer and a second material layer within the structure.

Each sacrificial material layer 42 other than a topmost sacrificial material layer 42 within the alternating stack (32, 42) laterally extends farther than any overlying sacrificial material layer 42 within the alternating stack (32, 42) in the terrace region. The stepped surfaces of the alternating stack (32, 42) continuously extend from a bottommost layer within the alternating stack (32, 42) (such as the bottommost insulating layer) to a topmost layer within the alternating stack (32, 42) (such as the topmost insulating layer 32T).

A retro-stepped dielectric material portion 65 (i.e., an insulating fill material portion) can be formed in the stepped cavity by deposition of a dielectric material therein. For example, a dielectric material such as silicon oxide can be deposited in the stepped cavity. Excess portions of the deposited dielectric material can be removed from above the top surface of the topmost insulating layer 32T, for example, by chemical mechanical planarization (CMP). The remaining portion of the deposited dielectric material filling the stepped cavity constitutes the retro-stepped dielectric material portion 65. As used herein, a “retro-stepped” element refers to an element that has stepped surfaces and a horizontal cross-sectional area that increases monotonically as a function of a vertical distance from a top surface of a substrate on which the element is present. If silicon oxide is employed for the retro-stepped dielectric material portion 65, the silicon oxide of the retro-stepped dielectric material portion 65 may, or may not, be doped with dopants such as B, P, and/or F.

Optionally, drain-select-level isolation structures (not shown) can be formed through the topmost insulating layer 32T and a subset of the sacrificial material layers 42 located at drain-select-levels. The drain-select-level isolation structures can be formed, for example, by forming drain-select-level lateral isolation trenches and filling the drain-select-level lateral isolation trenches with a dielectric material such as silicon oxide. Excess portions of the dielectric material can be removed from above the top surface of the topmost insulating layer 32T.

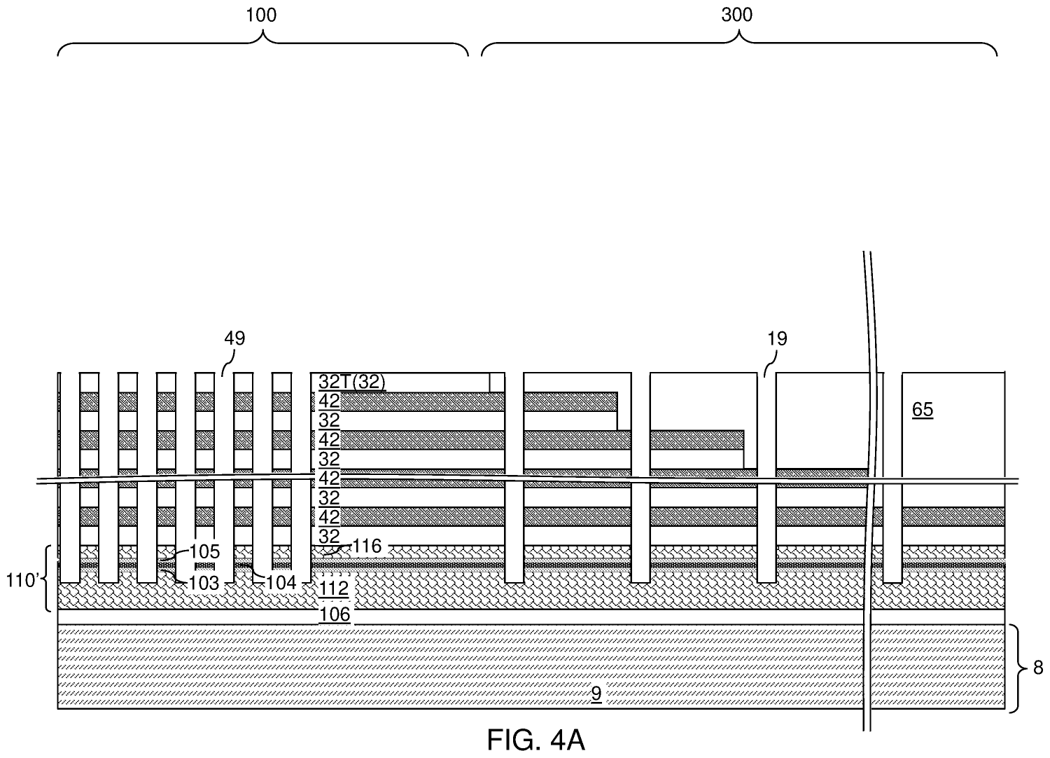

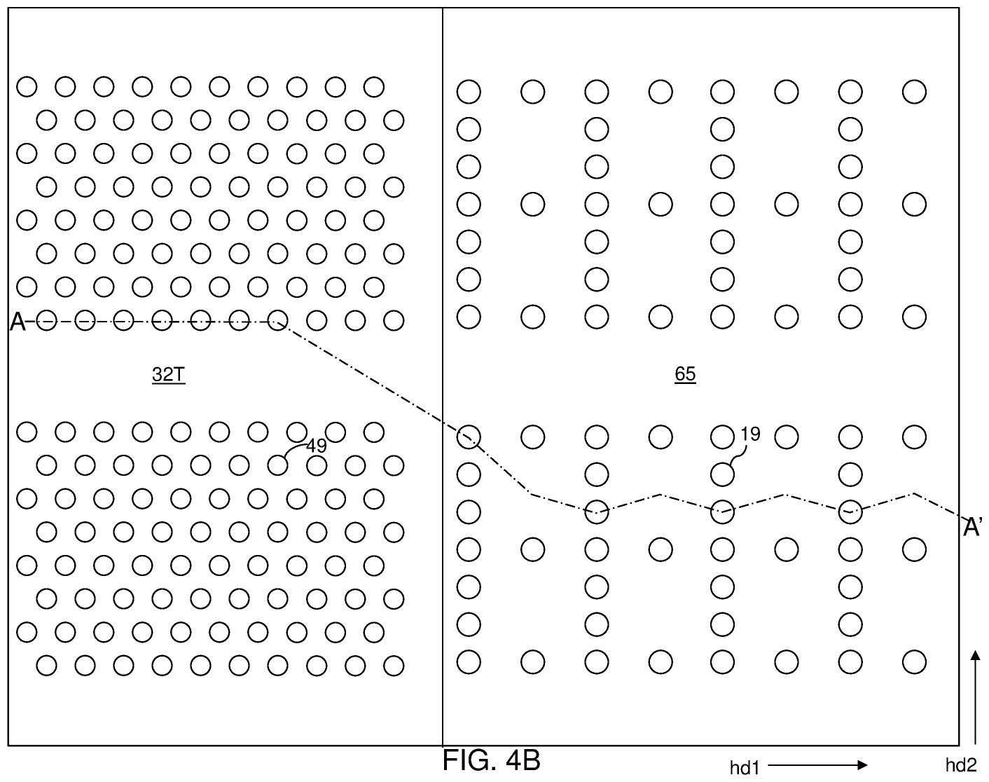

Referring to FIGS. 4A and 4B, an etch mask layer (such as a photoresist layer) can be formed over the alternating stack (32, 42), and can be lithographically patterned to form various openings therein. An anisotropic etch process can be performed to transfer the pattern of the openings in the etch mask layer through the alternating stack (32, 42). Various openings can be formed through the alternating stack (32, 42). The various openings may comprise memory openings 49 that are formed in the memory array region 100 and support openings 19 that are formed in the contact region 300. Each of the memory openings 49 and the support openings 19 can formed as a cylindrical cavity that vertically extends through the alternating stack (32, 42) and into the in-process source-level material layers 110′. In one embodiment, bottom surfaces of the memory openings 49 and the support openings 19 may be formed within the lower source-level semiconductor layer 112 or at an interface between the lower source-level semiconductor layer 112 and the backside insulating layer 106.

The support openings 19 may have a diameter in a range from 60 nm to 400 nm, such as from 120 nm to 300 nm, although lesser and greater thicknesses may be employed. The memory openings 49 may have a diameter in a range from 60 nm to 400 nm, such as from 120 nm to 300 nm, although lesser and greater thicknesses may be employed. The memory openings 49 and the support openings 19 may be formed through the alternating stack (32, 42), the upper source-level semiconductor layer 116, and the source-level sacrificial layer 104 and into the lower source-level semiconductor layer 112.

In one embodiment, the memory array region 100 may be laterally spaced apart from the contact region 300 along a first horizontal direction hd1. The memory openings 49 may comprise rows of memory openings 49 that are arranged along the first horizontal direction hd1 and laterally spaced apart along a second horizontal direction hd2 that is perpendicular to the first horizontal direction hd2. Multiple clusters of memory openings 49, each containing a respective two-dimensional periodic array of memory openings 49, may be formed in the memory array region 100. The clusters of memory openings 49 may be laterally spaced apart along the second horizontal direction hd2 by the areas of the line trenches 5 in the lower source-level semiconductor layer 112.

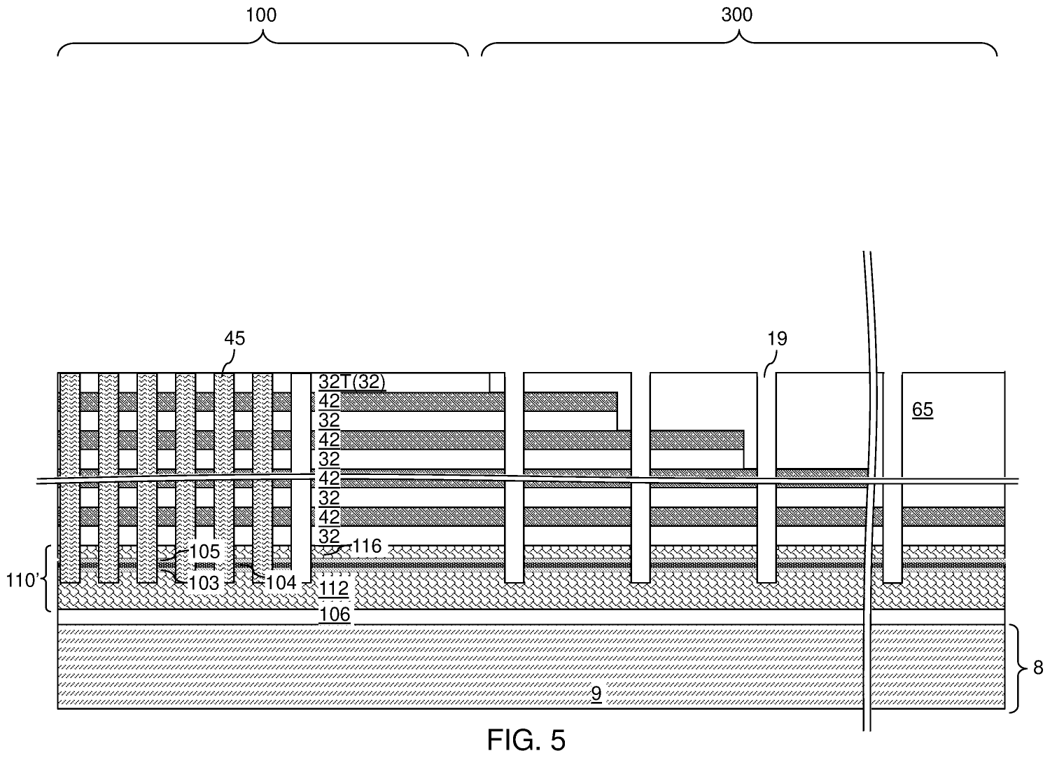

Referring to FIG. 5, an optional etch stop liner (not shown) and a sacrificial fill material (not shown) can be deposited in the memory openings 49 and the support openings. The optional etch stop liner (if present) comprises a thin dielectric material layer comprising silicon oxide, silicon nitride, or a dielectric metal oxide and having a thickness in a range from 1 nm to 6 nm. The sacrificial fill material may comprise a carbon-based material (such as amorphous carbon or diamond-like carbon), a semiconductor material (such as amorphous silicon or polysilicon), a dielectric fill material (such as borosilicate glass or organosilicate glass), or a polymer material. Excess portions of the sacrificial fill material can be removed from above the horizontal plane including the topmost layer of the alternating stack (32, 42) by a planarization process such as an etch back process. Remaining portions of the sacrificial fill material that fill the memory openings 49 constitute sacrificial memory opening fill structures 45. Remaining portions of the sacrificial fill material that fill the support openings 19 constitute sacrificial support opening fill structures (not shown).

A photoresist layer (not shown) can be applied over the alternating stack (32, 42) and the retro-stepped dielectric material portion 65, and can be lithographically patterned to cover the memory array region 100 without covering the contact region 300. The sacrificial support opening fill structures and portions of the optional etch stop liner in the contact region 300 can be removed selective to the materials of the retro-stepped dielectric material portion 65 and the alternating stack (32, 42). For example, an etch process or an ashing process may be employed to remove the sacrificial support opening fill structures and portions of the optional etch stop liner in the contact region 300. The photoresist layer can be subsequently removed.

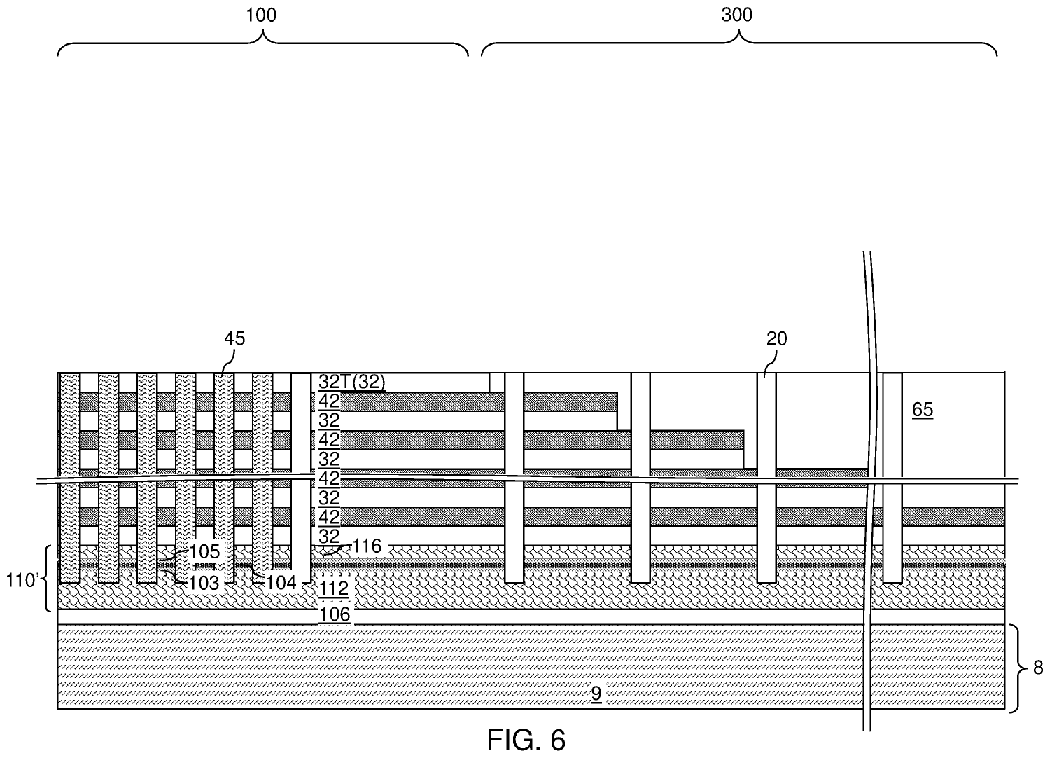

Referring to FIG. 6, a dielectric fill material such as silicon oxide can be deposited in the support openings 19 by a conformal deposition process. Excess portions of the dielectric fill material can be removed from above the top surface of the topmost insulating layer 32T, for example, by a recess etch process. Each portion of the dielectric fill material that fills a respective support opening 19 constitutes a support pillar structure 20, which can be employed to provide structural support to the insulating layers 32 and the retro-stepped dielectric material portion 65 during replacement of the sacrificial material layers 42 with electrically conductive layers.

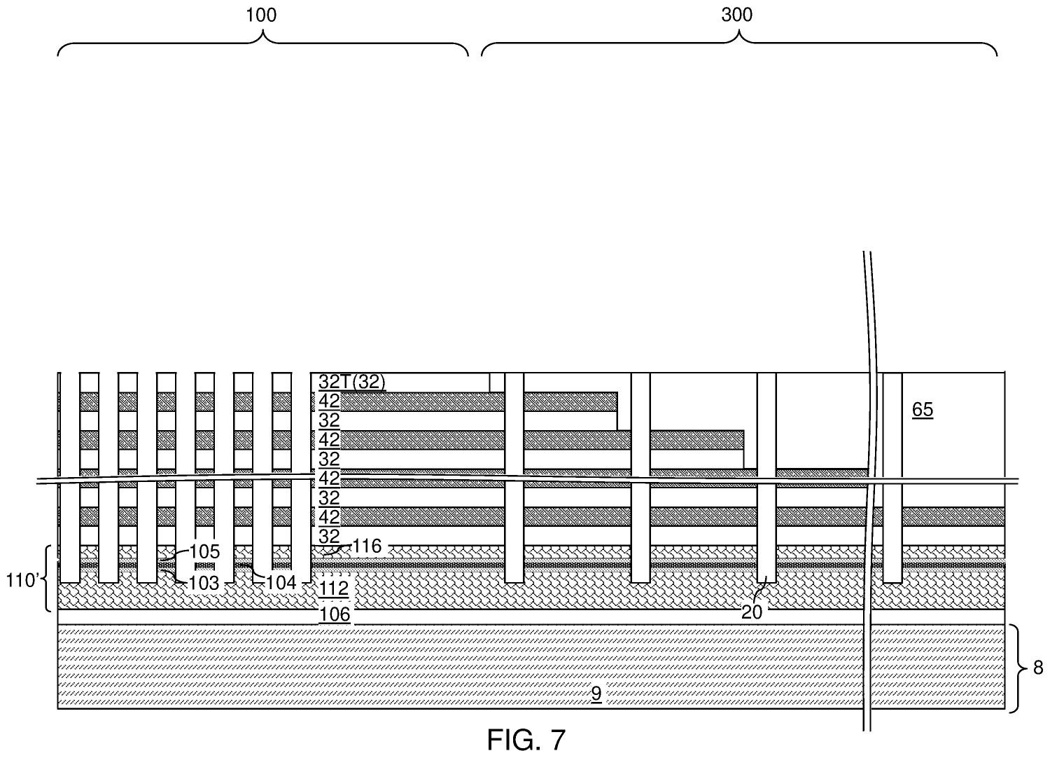

Referring to FIG. 7, the sacrificial memory opening fill structures 45 and portions of the optional etch stop liner in the memory array region 100 can be removed selective to the materials of the retro-stepped dielectric material portion 65 and the alternating stack (32, 42). For example, an etch process or an ashing process may be employed to remove the sacrificial memory opening fill structures and portions of the optional etch stop liner in the memory array region 100. Voids are formed in the volumes of the memory openings 49.

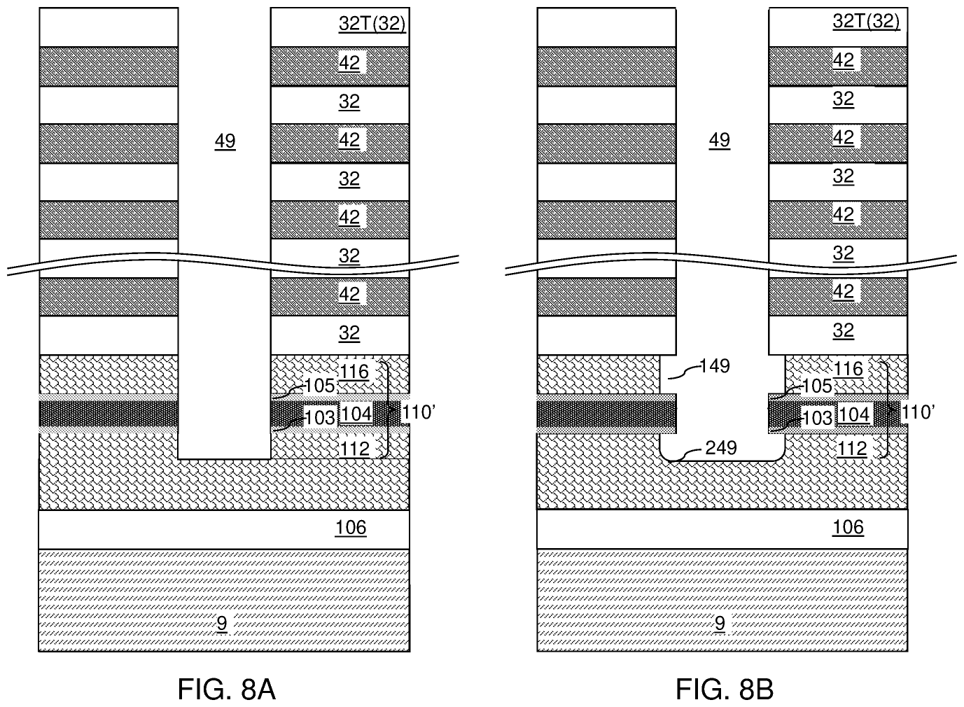

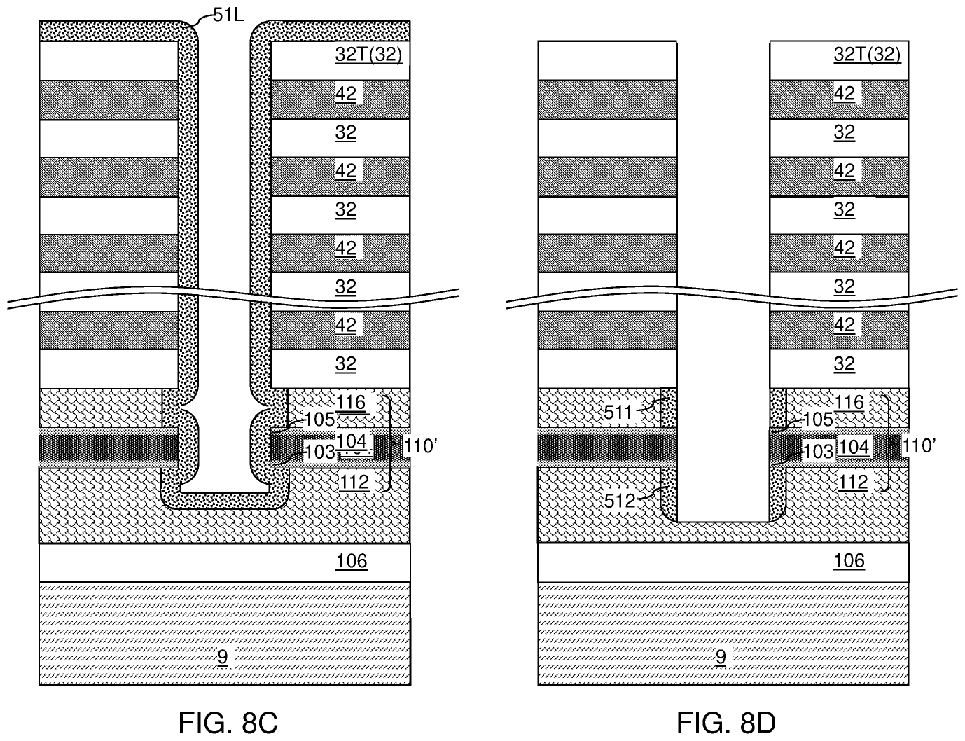

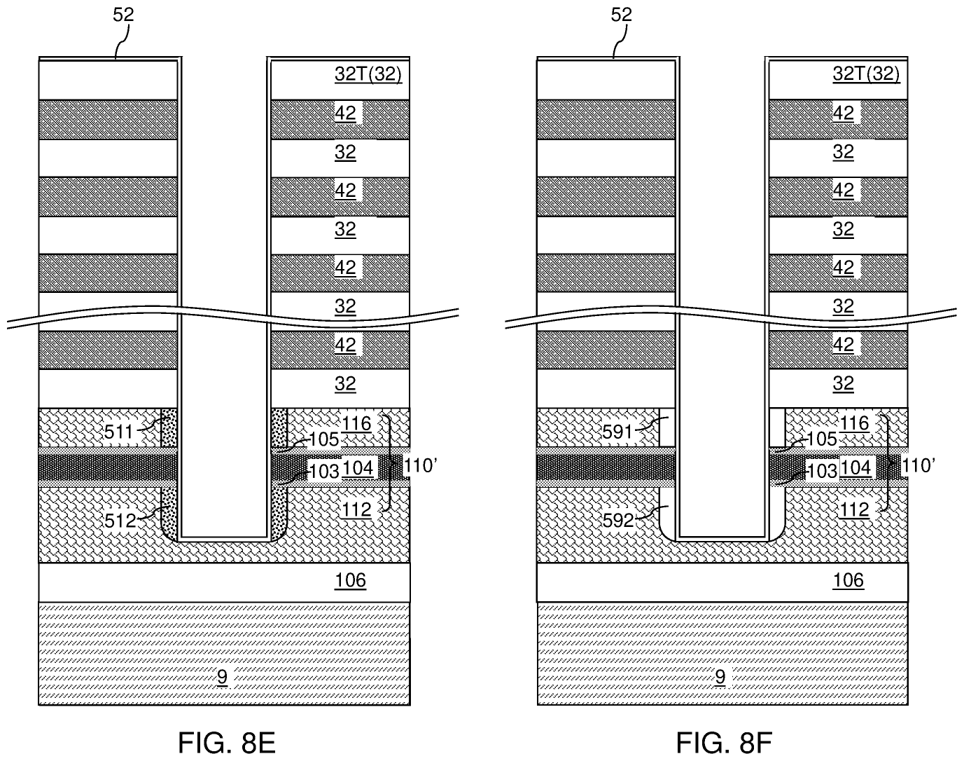

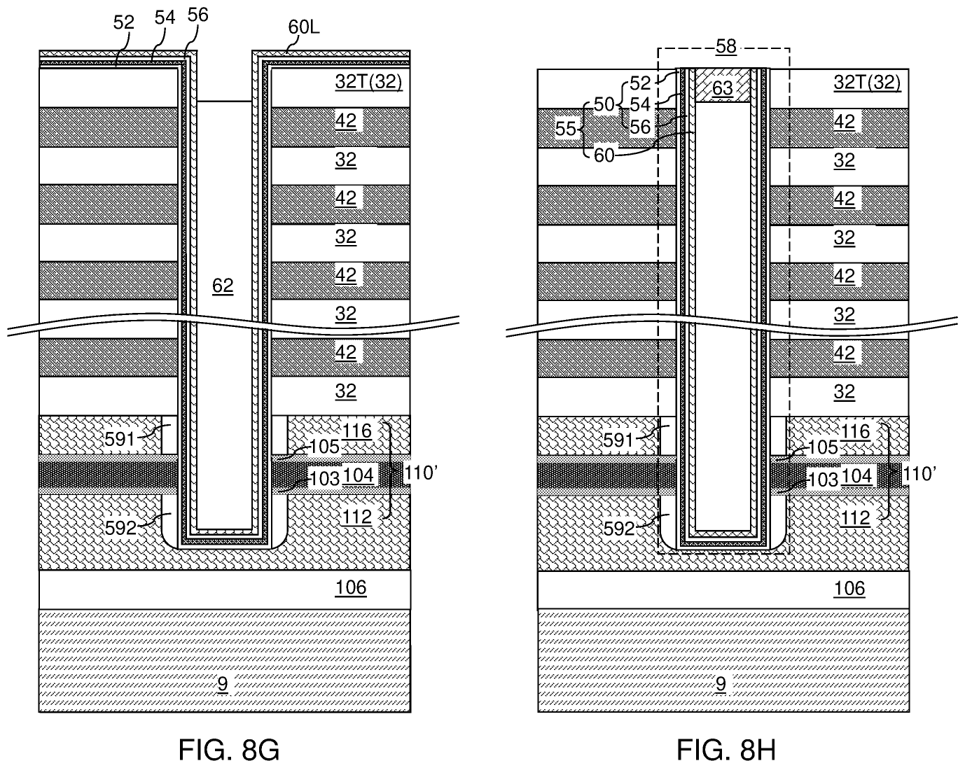

FIGS. 8A-8H are sequential vertical cross-sectional views of a memory opening 49 during formation of a memory opening fill structure 58 according to the first embodiment of the present disclosure.

Referring to FIG. 8A, a memory opening 49 within the first exemplary structure of FIG. 7 is illustrated, which comprises a cylindrical cavity that vertically extends through the alternating stack (32, 42) and an upper portion of the in-process source-level material layers 110′. In one embodiment, the memory opening 49 may comprise a bottom surface which is a recessed surface of the lower source-level semiconductor layer 112. The sidewall of the memory opening 49 may comprise cylindrical surface segments of the upper source-level semiconductor layer 116, the upper sacrificial liner 105, the source-level sacrificial layer 104, the lower sacrificial liner 103, and the lower source-level semiconductor layer 112.

Referring to FIG. 8B, a selective isotropic etch process can be performed to isotropically recess the upper source-level semiconductor layer 116 and the lower source-level semiconductor layer 112 selective to materials of the alternating stack (32, 42), the source-level sacrificial layer 104, the lower sacrificial liner 103, and the upper sacrificial liner 105. For example, a wet etch process using hot trimethyl-2 hydroxyethyl ammonium hydroxide (“hot TMY”) or tetramethyl ammonium hydroxide (TMAH) may be performed to isotropically recess the upper source-level semiconductor layer 116 and the lower source-level semiconductor layer 112 selective to materials of the alternating stack (32, 42), the source-level sacrificial layer 104, the lower sacrificial liner 103, and the upper sacrificial liner 105. A first annular cavity 149 and a second annular cavity 249 may be formed by performing a selective isotropic etch process that etches the semiconductor materials of the upper source-level semiconductor layer 116 and the lower source-level semiconductor layer 112 selective to the material of the source-level sacrificial layer 104.

The first annular cavity 149 (which is also referred to as an upper annular cavity) is formed at the level of the upper source-level semiconductor layer 116, and the second annular cavity 249 (which is also referred to as a lower annular cavity) is formed at the level of the lower source-level semiconductor layer 112. The duration of the isotropic etch process may be selected such that the lateral recess distance of the isotropic etch process is less than one half of lateral spacing between neighboring pairs of memory openings 49 within the in-process source-level material layers 110′. Thus, the first annular cavities 149 of the memory openings 49 do not merge with each other, and the second annular cavities 249 of the memory openings 49 do not merge with each other. In an illustrative example, the lateral recess distance, i.e., the etch distance, of the isotropic etch process may be in a range from 3nm to 60 nm, such as form 6 nm to 30 nm, although lesser and greater lateral etch distances may also be employed.

In summary, the memory opening 49 vertically extends through the alternating stack (32, 42) and an upper portion of the in-process source-level material layers 110′, and includes a first annular cavity 149 located at a level of the upper source-level semiconductor layer 116 and undercutting the alternating stack (32, 42), and also includes a second annular cavity 249 located at a level of the lower source-level semiconductor layer 112.

Referring to FIG. 8C, a sacrificial fill material layer 51L can be formed in peripheral portions of the memory openings 40 and over the topmost insulating layer 32T by a conformal deposition process, such as a chemical vapor deposition process. The sacrificial fill material layer 51L comprises a sacrificial material that can be removed selective to materials of the insulating layers 32 and the in-process source-level material layers 110′. In one embodiment, the sacrificial fill material layer 51L comprises a carbon-based material, a polymer material, or a thermally-decomposable organic material that volatilizes upon decomposition. In an illustrative example, the sacrificial fill material layer 51L comprises a carbon-based polymer material that can be decomposed at a temperature in a range from 400 degrees Celsius to 700 degrees Celsius into a volatile carbon-containing gas. Exemplary carbon-based polymer materials include polyacrylonitrile (PAN), polycarbonate (PC), polyvinyl chloride (PVC), polyethylene terephthalate (PET), phenolic resins, polyurethane (PU), and polypropylene (PP). The sacrificial fill material layer 51L may be formed at a low temperature (e.g., between 70 and 200 degrees Celsius) with a thickness which is less than one half of the lateral dimension of the memory opening 49 at the level of the alternating stacks (32, 42), and is greater than the lateral recess distance of the isotropic etch process that forms the first annular cavity 149 and the second annular cavity 249. The sacrificial fill material layer 51L may optionally be annealed at a temperature (e.g., between 200 and 280degrees Celsius for 2 to 10 minutes) which is lower than its decomposition temperature to reflow it such that it completely fills the first and second annular cavities (149, 249).

Referring to FIG. 8D, portions of the sacrificial fill material layer 51L located outside the volumes of the first annular cavities 149 and the second annular cavities 249 of the memory openings 49 are removed. The removal process may comprise an anisotropic etch process and/or a partial vaporization process. The partial vaporization process may comprise an anneal at a temperature close to but below a complete decomposition temperature of the sacrificial fill material layer 51L. For example, for a polymer sacrificial fill material layer 51L, the partial vaporization anneal may be conducted at a temperature between 280 and 330 degrees Celsius for 2 to 10 minutes. Each remaining portion of the sacrificial fill material layer 51L that fills a first annular cavity 149 constitutes a first annular cavity fill structure 511 (which is also referred to as an upper annular cavity fill structure), and each remaining portion of the sacrificial fill material layer 51L that fills a second annular cavity 249 constitutes a second annular cavity fill structures 512 (which is also referred to as a lower annular cavity fill structure). In one embodiment, inner cylindrical sidewalls of the first annular cavity fill structure 511 and the second annular cavity fill structure 512 in a memory opening 49 may be vertically coincident with cylindrical sidewalls of the alternating stack (32, 42) around the memory opening 49. As used herein, a first surface and a second surface are vertically coincident among one another if the second surface overlies or underlies the first surface and if there exists a vertical plane including the first surface and the second surface.

In one embodiment, After forming the first and second annular cavity fill structures (511, 512) the depth of the memory opening 49 may optionally be increased. For example, the exposed portion of the lower source-level semiconductor layer 112 may be recessed by reactive ion etching. In this embodiment, the bottom surface of the memory opening 49 extends below the bottom surface of the second annular cavity fill structure 512.

Referring to FIG. 8E, a blocking dielectric layer 52 can be conformally deposited on physically exposed surfaces of the first exemplary structure. Thus, the blocking dielectric layer 52 can be deposited directly on the physically exposed sidewalls of the alternating stacks (32, 42), the annular cavity fill structures (511, 512), the source-level sacrificial layer 104, and the sacrificial liners (103, 105), and on the top surface of the topmost insulating layer 32T. According to an aspect of the present disclosure, the blocking dielectric layer 52 has a material composition and a thickness that allows passage of volatile gases therethrough. For example, the blocking dielectric layer 52 may comprise a silicon oxide material formed by thermal decomposition of tetraethylorthosilicate (TEOS) at a temperature (e.g., 125 to 250 degrees Celsius) that is below the decomposition or partial vaporization temperature of the annular cavity fill structures (511, 512). The blocking dielectric layer 52 and may have a thickness in a range from 1 nm to 4 nm, such as from 2 nm to 3 nm.

Referring to FIG. 8F, an anneal process can be performed at above the decomposition temperature of the annular cavity fill structures (511, 512) to decompose and completely vaporize the material of the annular cavity fill structures (511, 512). The elevated temperature of the anneal process may be in a range from 350 degrees Celsius to 850 degrees Celsius, such as from 380 degrees Celsius to 450 degrees Celsius. The sacrificial fill material of the annular cavity fill structures (511, 512) is decomposed into volatile gases, which diffuse through the blocking dielectric layer 52 into the memory opening 49. The volatile gases (e.g., carbon containing gases) are then pumped out of the process chamber used to perform the decomposition anneal process. The duration of the anneal process can be selected such that the entirety of the sacrificial fill material of the annular cavity fill structures (511, 512) is volatilized and is removed from the volumes of the annular cavity fill structures (511, 512) during the anneal process, such a duration of 5 to 10 minutes. The anneal may be performed in a vacuum or in an oxidizing ambient, such as in an oxygen and/or water vapor ambient. The oxidizing ambient may assist in chemically decomposing the carbon based annular cavity fill structures (511, 512). For example, a catalytic water vapor generation process may be used to provide a water vapor oxidizing ambient.

A first annular cavity 591 is formed in the volume from which the sacrificial fill material of a first annular cavity fill structure 511 is removed, and a second annular cavity 592 is formed in the volume from which the sacrificial fill material of a second annular cavity fill structure 512 is removed. Each of the annular cavities (591, 592) may be an encapsulated cavity, i.e., cavities that are not connected to any outside gaseous ambient. Upon gradual backfill of the process chamber with clean dry air or an inert gas, the clean dry air or the inert gas can diffuse into the volumes of the annular cavities (591, 592). Thus, the first annular cavity 591 and the second annular cavity 592 in each memory opening 49 may be backfilled with clean dry air (e.g., comprise an air gap) or with an inert gas (such as nitrogen, argon, etc.).

In summary, the first annular cavity fill structures 511 and the second annular cavity fill structures 512 may be removed after formation of the blocking dielectric layer 52. If the first annular cavity fill structures 511 and the second annular cavity fill structures 512 comprise a carbon-based material, the carbon-based material may be converted into a vaporized gas, which passes through the blocking dielectric layer 52 into the memory opening 49.

Referring to FIG. 8G, a layer stack (54, 56, 60L) including a memory material layer 54, an optional dielectric liner 56, and a semiconductor channel material layer 60L can be sequentially deposited by conformal deposition processes. The layer stack (54, 56, 60L) can be formed outside the volumes of the annular cavities (591, 592).

The memory material layer 54 may comprise any memory material that can store a data bit. The data bit may be stored in the form of electrical charges trapped therein, in the form of a resistive state of a material due to changes in the material phase or ferroelectric polarization. In one embodiment, the memory material layer 54 may comprise a charge storage layer including a dielectric charge trapping material, which can be, for example, silicon nitride. Alternatively, the memory material layer 54 can include a conductive material such as doped polysilicon or a metallic material that is patterned into multiple electrically isolated portions (e.g., floating gates), for example, by being formed within lateral recesses into sacrificial material layers 42. In one embodiment, the memory material layer 54 includes a silicon nitride layer. In one embodiment, the sacrificial material layers 42 and the insulating layers 32 can have vertically coincident sidewalls, and the memory material layer 54 can be formed as a single layer.

The optional dielectric liner 56, if present, comprises a dielectric material. In one embodiment, if the memory material layer 54 comprises a charge storage layer, then the dielectric liner 56 may comprise a tunneling dielectric layer through which charge tunneling can be performed under suitable electrical bias conditions. The charge tunneling may be performed through hot-carrier injection or by Fowler-Nordheim tunneling induced charge transfer depending on the mode of operation of the three-dimensional NAND memory device to be formed. The dielectric liner 56 can include silicon oxide, silicon nitride, silicon oxynitride, dielectric metal oxides (such as aluminum oxide and hafnium oxide), dielectric metal oxynitride, dielectric metal silicates, alloys thereof, and/or combinations thereof. In one embodiment, the dielectric liner 56 can include a stack of a first silicon oxide layer, a silicon oxynitride layer, and a second silicon oxide layer, which is commonly known as an ONO stack. In one embodiment, the dielectric liner 56 can include a silicon oxide layer that is substantially free of carbon or a silicon oxynitride layer that is substantially free of carbon. The thickness of the dielectric liner 56 can be in a range from 2 nm to 20 nm, although lesser and greater thicknesses can also be employed.

The semiconductor channel material layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel material layer includes amorphous silicon or polysilicon. The semiconductor channel material layer can have a doping of a first conductivity type. The semiconductor channel material layer can be formed by a conformal deposition method such as low pressure chemical vapor deposition (LPCVD). The thickness of semiconductor channel material layer can be in a range from 2 nm to 10 nm, although lesser and greater thicknesses can also be employed.

A dielectric fill material, such as silicon oxide, can be deposited in remaining cavities in the memory openings 49, and can be vertically recessed such that top surfaces of remaining portions of the dielectric fill material are formed at, or about, the horizontal plane including a bottom surface of the topmost insulating layer 32T. Each remaining portion of the dielectric fill material constitutes a dielectric core 62.

Referring to FIG. 8H, doped semiconductor material having a doping of a second conductivity type can be deposited within each recessed region above the dielectric cores 62. The deposited semiconductor material can have a doping of a second conductivity type that is the opposite of the first conductivity type. For example, if the first conductivity type is p-type, the second conductivity type is n-type, and vice versa. The dopant concentration in the deposited semiconductor material can be in a range from 5.0×10¹⁸/cm³ to 2.0×10²¹/cm³, although lesser and greater dopant concentrations can also be employed. The doped semiconductor material can be, for example, doped polysilicon.

Portions of the deposited semiconductor material having a doping of the second conductivity type, the semiconductor channel material layer 60L, the optional dielectric liner 56, the memory material layer 54, and the blocking dielectric layer 52 that overlie the horizonal plane including the top surface of the topmost insulating layer 32T can be removed by a planarization process. The planarization process may employ, for example, a chemical mechanical polishing (CMP) process and/or a recess etch process.

Each remaining portion of the doped semiconductor material having a doping of the second conductivity type constitutes a drain region 63. Each remaining portion of the semiconductor channel material layer 60L (which has a doping of the first conductivity type) constitutes a vertical semiconductor channel 60. Each contiguous set of the blocking dielectric layer 52, the memory material layer 54, and the optional dielectric liner 56 collectively constitute a memory film 50, which may store electrical charges or ferroelectric polarization with a macroscopic retention time. As used herein, a macroscopic retention time refers to a retention time suitable for operation of a memory device as a permanent memory device such as a retention time in excess of 24 hours.

Each combination of a memory film 50 and a vertical semiconductor channel 60 within a memory opening 49 constitutes a memory stack structure 55. The memory stack structure 55 is a combination of the vertical semiconductor channel 60, the optional dielectric liner 56, the plurality of memory elements which comprise portions of the memory material layer 54, and the blocking dielectric layer 52. An entire set of material portions that fills a memory opening 49 is herein referred to as a memory opening fill structure 58.

Each memory film 50 is formed outside volumes of the annular cavities (591, 592). Thus, each memory opening fill structure 58 may be formed in a volume of the memory opening 49 other than the volumes of the annular cavities (591, 592).

While an embodiment is described in which the memory opening fill structures 58 are formed after formation of the dielectric support pillar structures 20, the order of the set of processing steps for forming the memory opening fill structures 58 and the set of processing steps for forming the dielectric support pillar structures 20 may be reversed. In this case, the memory opening fill structures 58 may be formed prior to formation of the dielectric support pillar structures 20. In another embodiment, the support pillar structures 20 and the memory opening fill structures 58 are formed during the same process steps and comprise the same set of materials. Thus, the support pillar structures 20 may be formed prior to, after or at the same time as the memory opening fill structure 58.

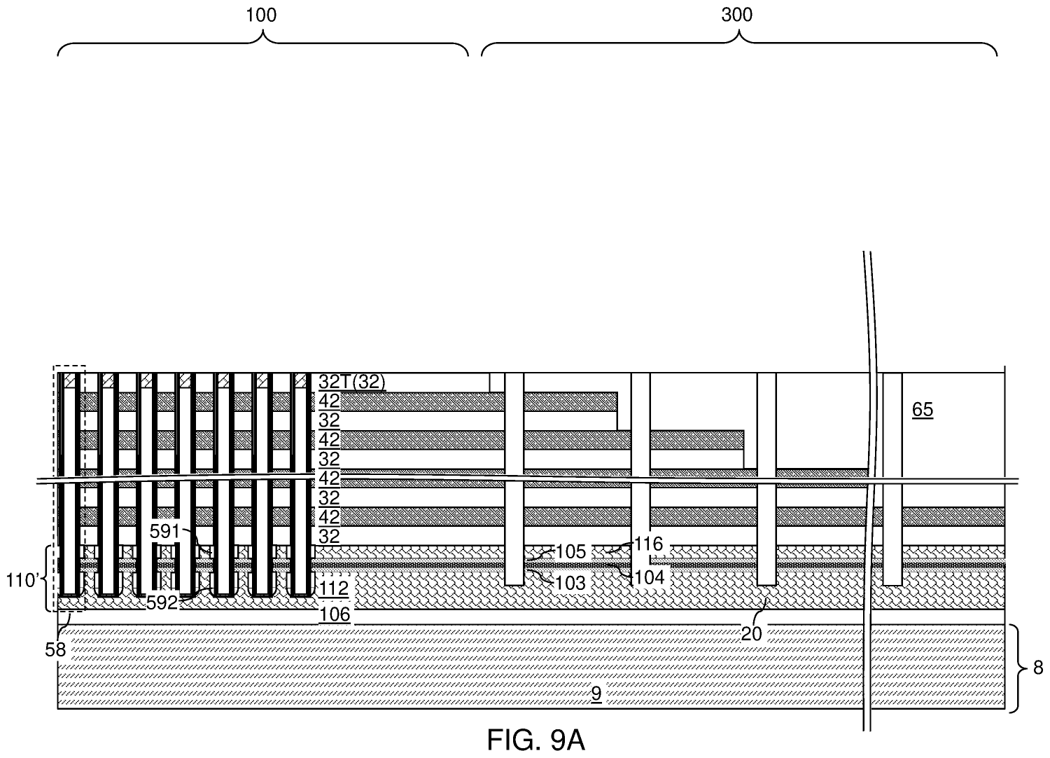

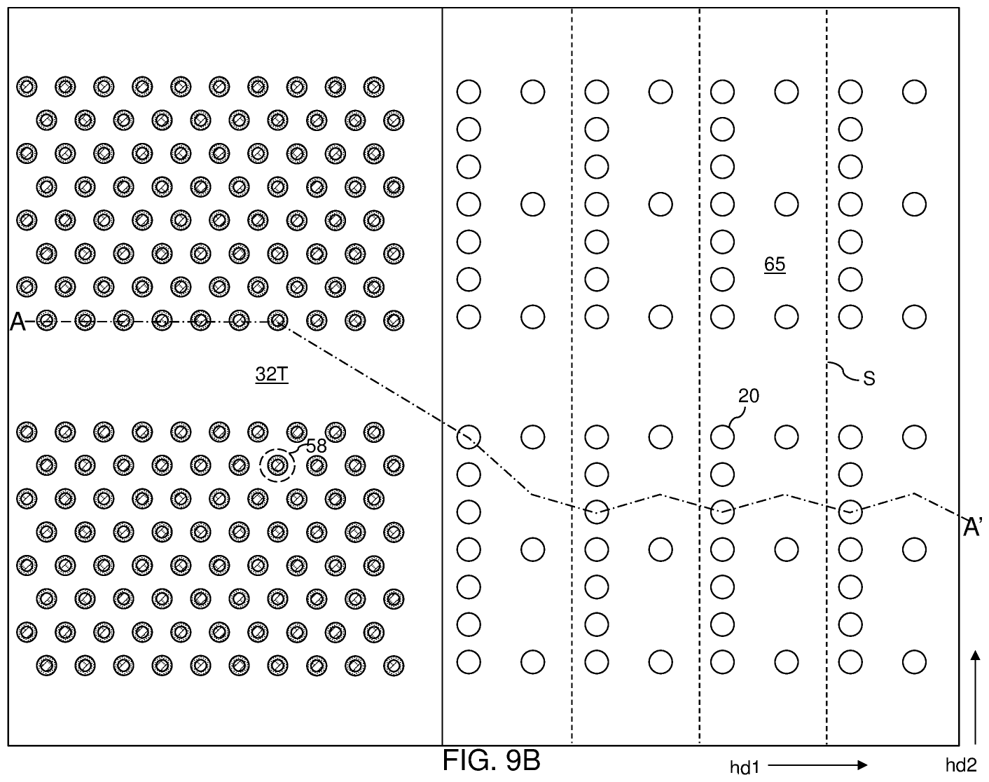

Referring to FIGS. 9A and 9B, the first exemplary structure is illustrated after formation of memory opening fill structures 58 and support pillar structures 20.

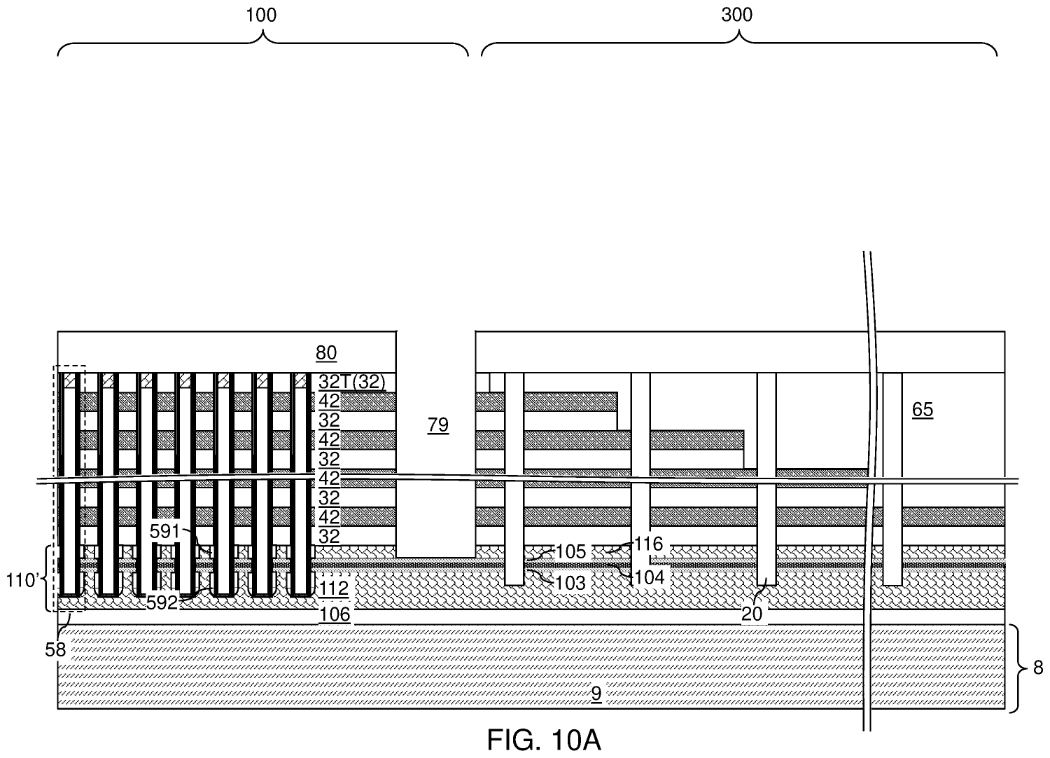

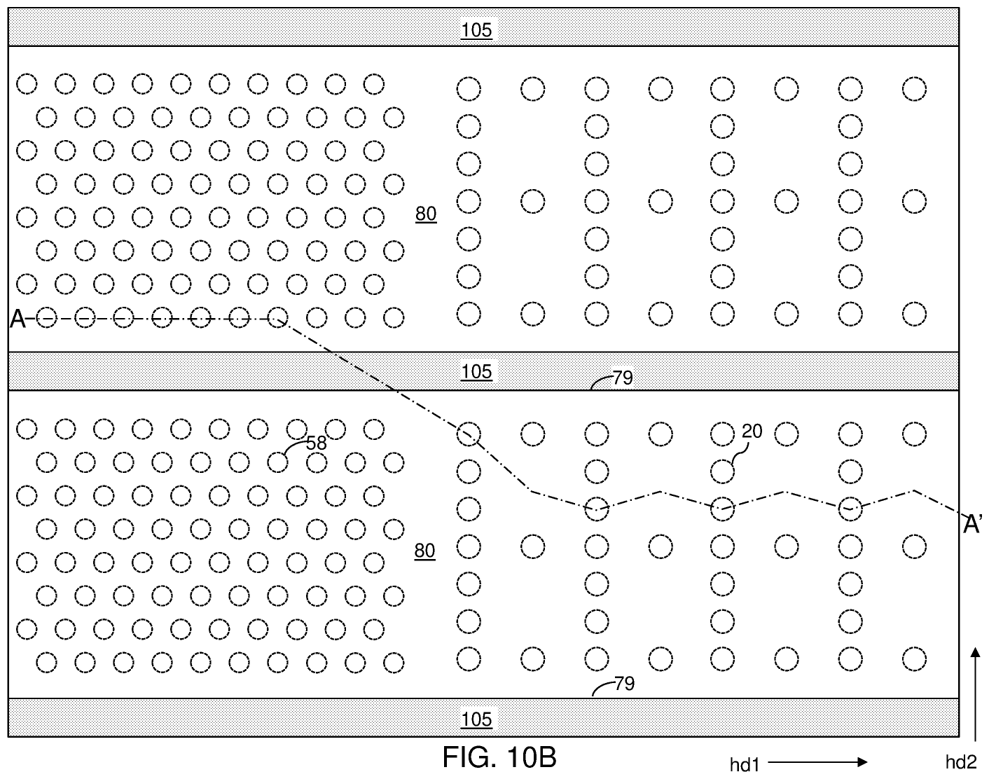

Referring to FIGS. 10A and 10B, a dielectric material such as undoped silicate glass or a doped silicate glass can be deposited over the alternating stack (32, 42) to form a contact-level dielectric layer 80. The thickness of the contact-level dielectric layer 80 may be in a range from 100 nm to 600 nm, such as from 200 nm to 400 nm, although lesser and greater thicknesses may also be employed.

A photoresist layer (not shown) can be applied over the contact-level dielectric layer 80, and can be lithographically patterned to form elongated openings that laterally extend along the first horizontal direction hd1 between neighboring clusters of memory opening fill structures 58. An anisotropic etch process can be performed to transfer the pattern of the openings in the photoresist layer through the contact-level dielectric layer 80, the alternating stack (32, 42), the retro-stepped dielectric material portion 65, and the upper source-level semiconductor layer 116. A terminal step of the anisotropic etch process may etch the semiconductor material of the upper source-level semiconductor layer 116 selective to the material of the upper sacrificial liner 105.

Lateral isolation trenches 79 laterally extending along the first horizontal direction hd1 can be formed through the alternating stack (32, 42), the retro-stepped dielectric material portion 65, the contact-level dielectric layer 80, and the in-process source-level material layers 110′. The alternating stack (32, 42) can be divided into multiple alternating stacks (32, 42), each laterally extending along the first horizontal direction (e.g., word line direction) hd1 and laterally spaced apart along the second horizontal direction (e.g., bit line direction) hd2. Each of the lateral isolation trenches 79 may comprise a respective pair of lengthwise sidewalls that are parallel to the first horizontal direction hd1 and vertically extend from the backside insulating layer 106 to the top surface of the contact-level dielectric layer 80. A top surface of the backside insulating layer 106 can be physically exposed underneath each lateral isolation trench 79. The lateral isolation trenches 79 isolate adjacent alternating stacks (32, 42) along the second horizontal direction hd2. The photoresist layer can be subsequently removed, for example, by ashing.

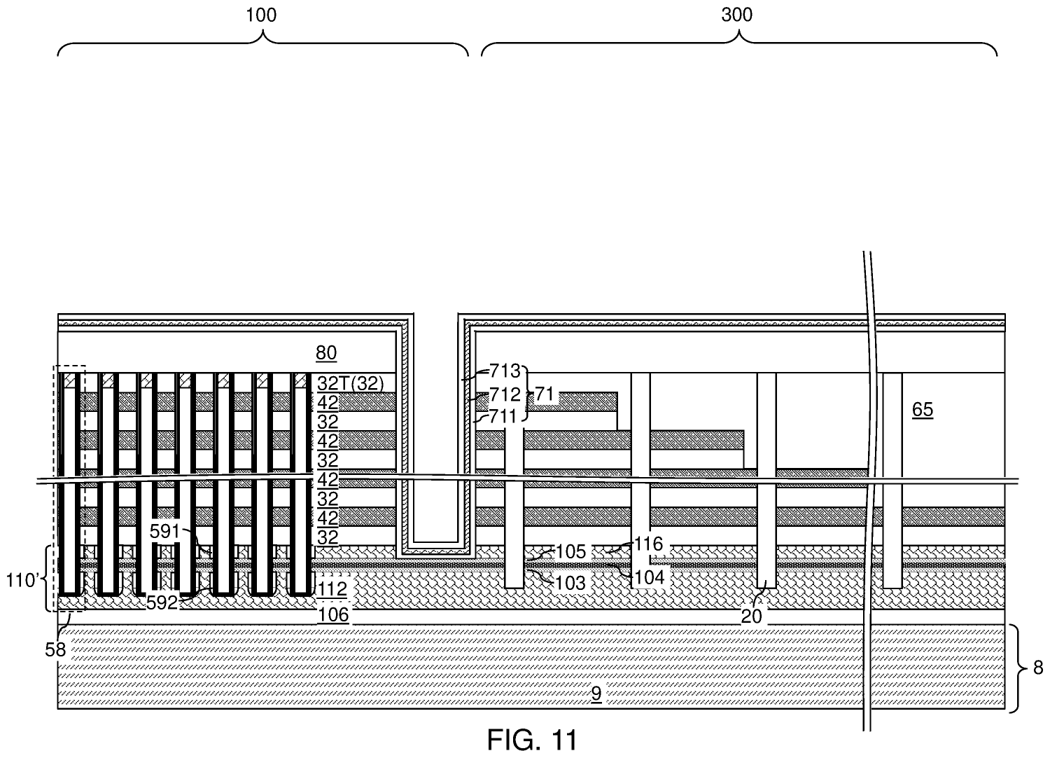

Referring to FIG. 11, sacrificial spacer layers 71 can be conformally deposited in peripheral regions of the lateral isolation trenches 79 and above the contact-level dielectric layer 80. In one embodiment, the sacrificial spacer layers 71 may comprise a first sacrificial spacer layer 711, a second sacrificial spacer layer 712, and a third sacrificial spacer layer 713. Each of the sacrificial spacer layers 71 may comprise a respective sacrificial spacer material that can be employed to prevent etching of the sacrificial material layers 42 during replacement of the source-level sacrificial layer 104 with a source contact layer. In an illustrative example, the first sacrificial spacer layer 711 may comprise a first silicon oxide material, the second sacrificial spacer layer 712 may comprise a semiconductor material, such as amorphous silicon, and the third sacrificial spacer layer 713 may comprise a second silicon oxide material. Each of the first, second, and third sacrificial spacer layers (711, 712, 713) may have a respective thickness in a range from 10 nm to 50 nm, such as from 15 nm to 30nm, although lesser and greater thicknesses may also be employed.

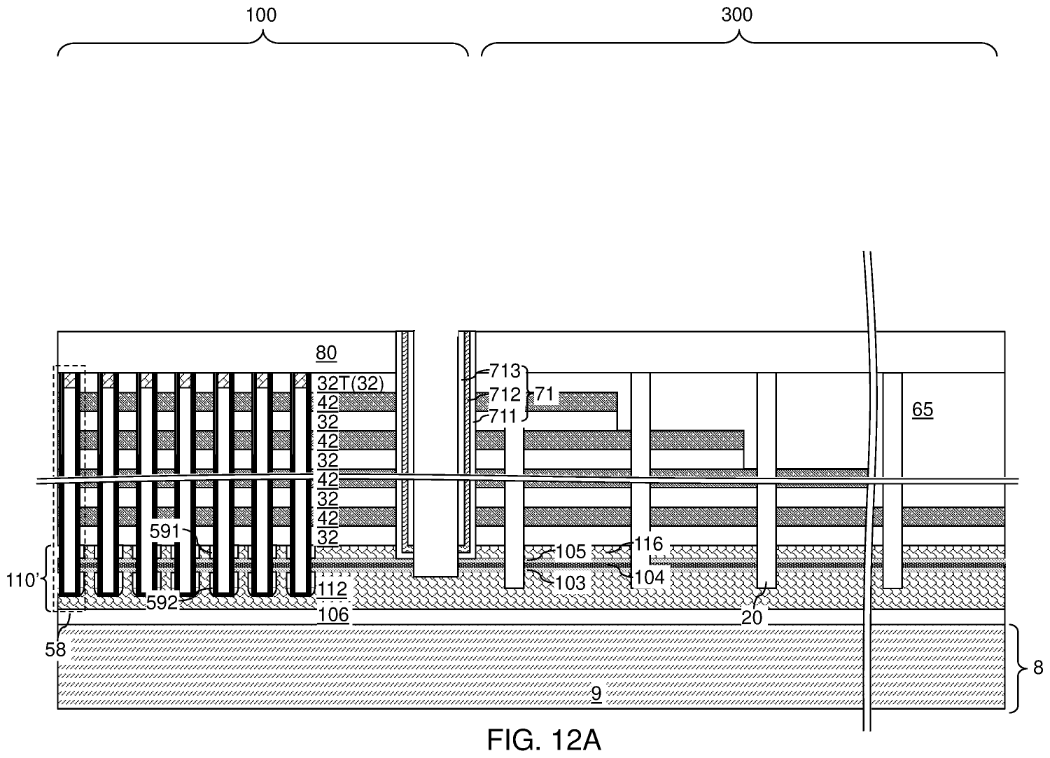

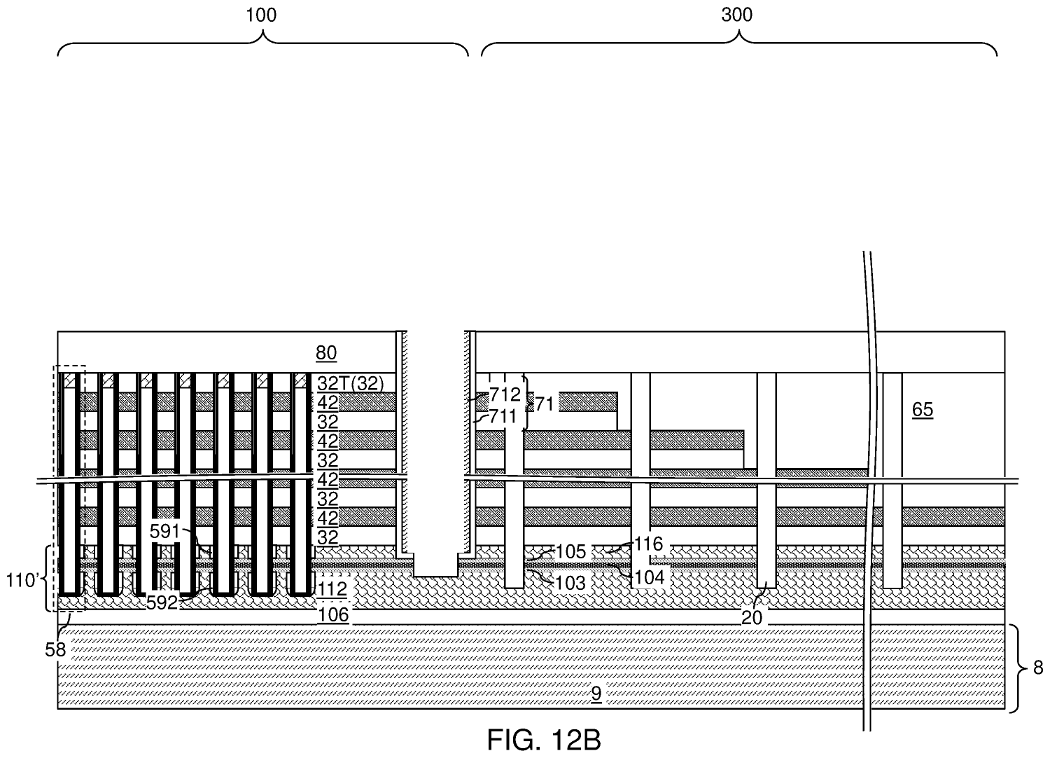

Referring to FIG. 12A, an anisotropic etch process can be performed to etch horizontally-extending portions of the sacrificial spacer layers 71. The anisotropic etch process may be extended to etch through portions of the optional upper sacrificial liner 105. the source-level sacrificial layer 104, and the optional lower sacrificial liner 103, and optionally to etch into the lower source-level semiconductor layer 112 that underlie the voids within the lateral isolation trenches 79. Each remaining portion of the sacrificial spacer layers 71 in the lateral isolation trenches 79 may have a tubular configuration, and may vertically extend through the entirety of the alternating stacks (32, 42).

Referring to FIG. 12B, the remaining vertical portions of the third sacrificial spacer layer 713 may be removed by selective etching. For example, if the third sacrificial spacer layer 713 comprises silicon oxide, then the selective etching may comprise a dilute hydrofluoric acid etching step.

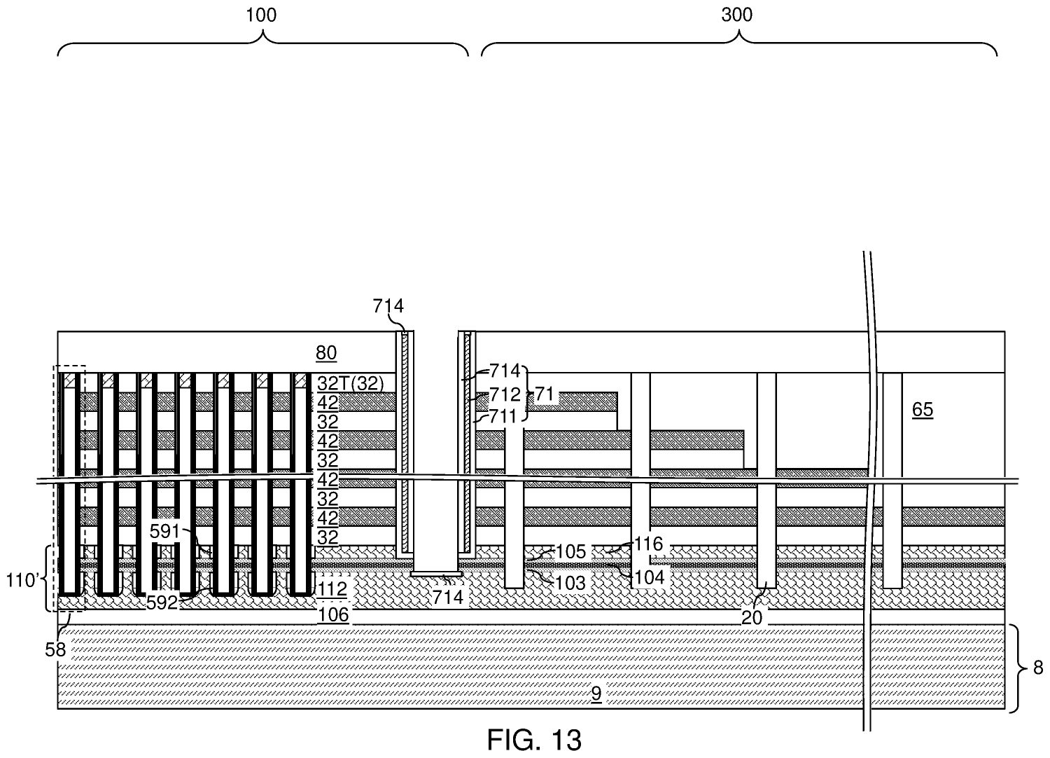

Referring to FIG. 13, an oxidation process (such as a thermal oxidation process or a plasma oxidation process) may be performed to convert physically exposed surface portions of semiconductor material layers (112, 712) (e.g., silicon layers) into sacrificial semiconductor oxide liners 714, which may be silicon oxide liners.

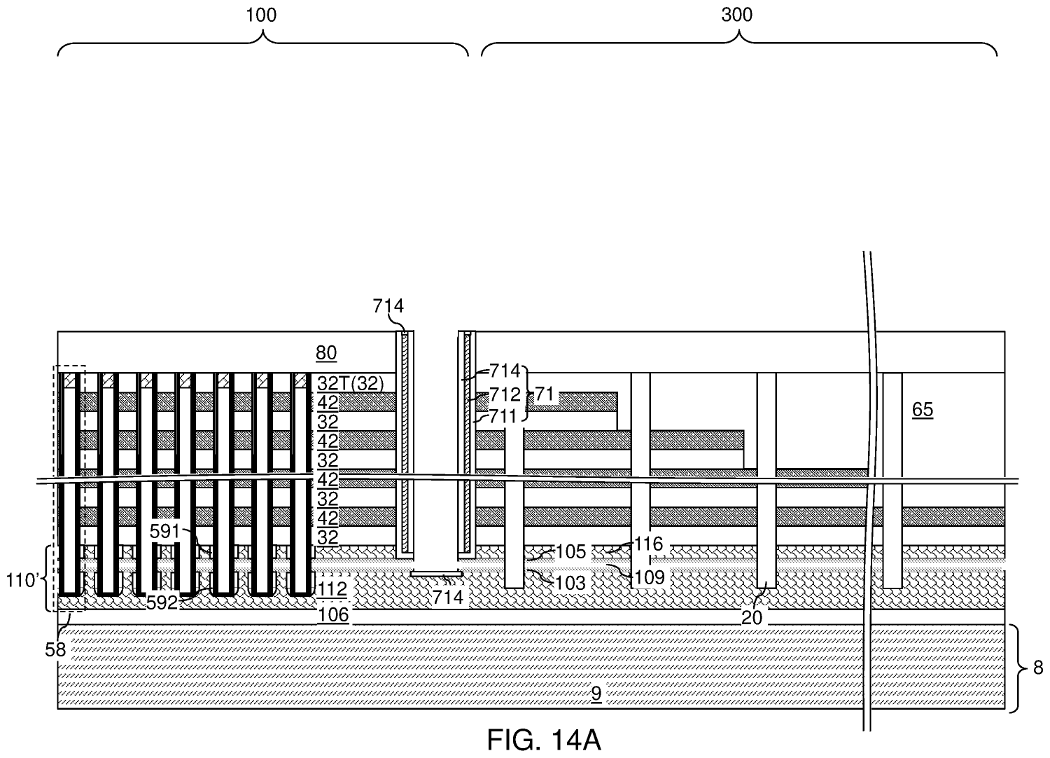

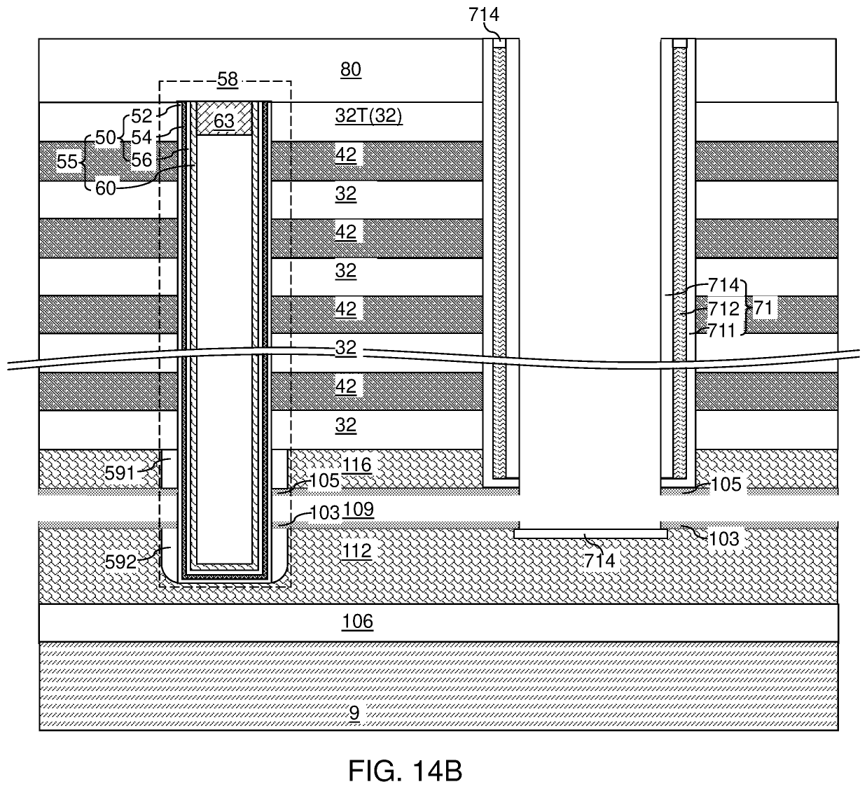

Referring to FIGS. 14A and 14B, an etchant that etches the material of the source-level sacrificial layer 104 selective to the materials of the semiconductor oxide liners 714, the contact-level dielectric layer 80, the retro-stepped dielectric material portion 65, the lower source-level semiconductor layer 112, the upper source-level semiconductor layer 116, the upper sacrificial liner 105 (if present), and the lower sacrificial liner 103 (if present) may be introduced into the lateral isolation trenches 79 by performing an isotropic etch process. For example, if the source-level sacrificial layer 104 comprises silicon nitride, a wet etch process using hot phosphoric acid may be used to remove the source-level sacrificial layer 104 selective to the silicon oxide liners 714, the silicon oxide contact-level dielectric layer 80, the silicon oxide retro-stepped dielectric material portion 65, the silicon lower source-level semiconductor layer 112, and the silicon upper source-level semiconductor layer 116. A source cavity 109 is formed in the volume from which the source-level sacrificial layer 104 is removed.

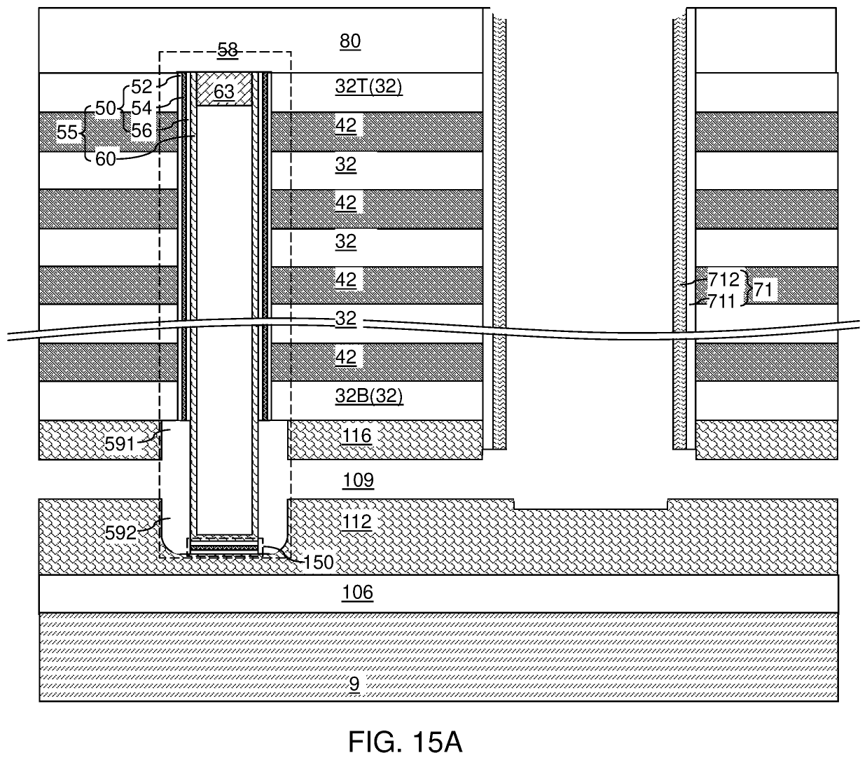

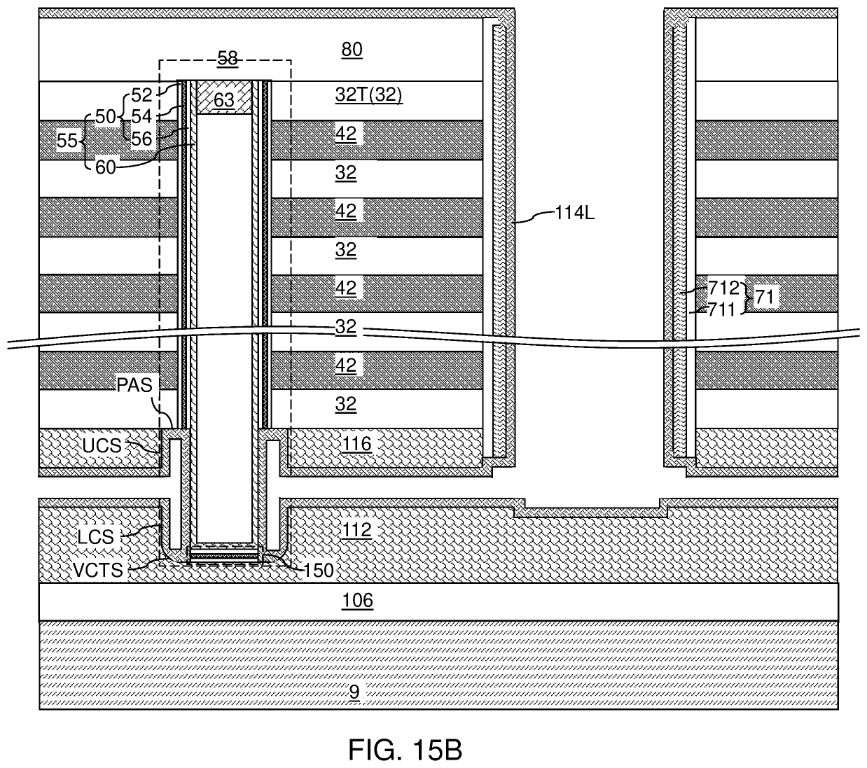

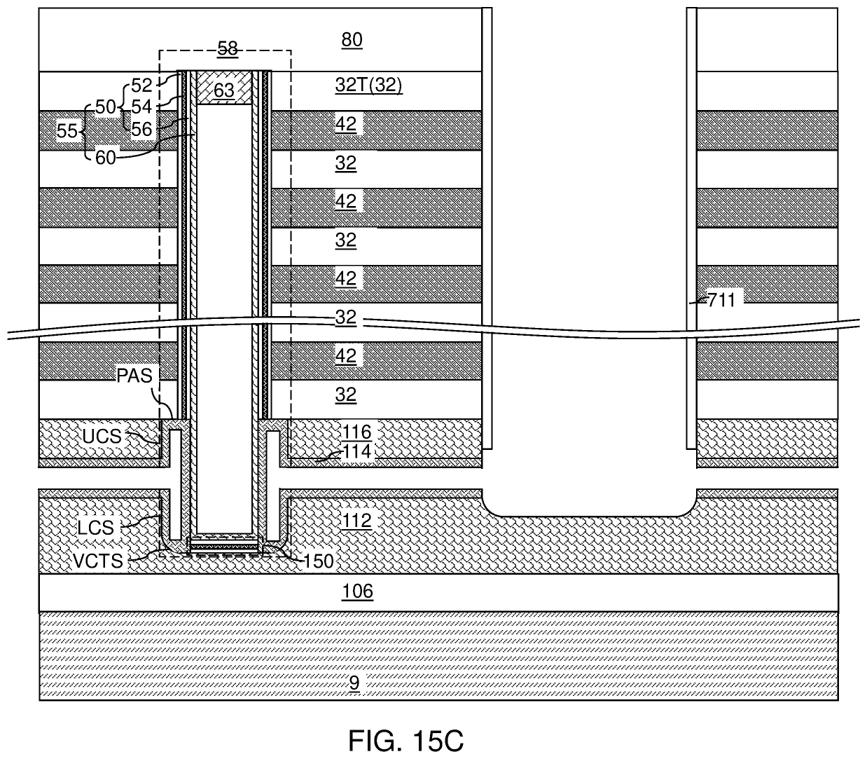

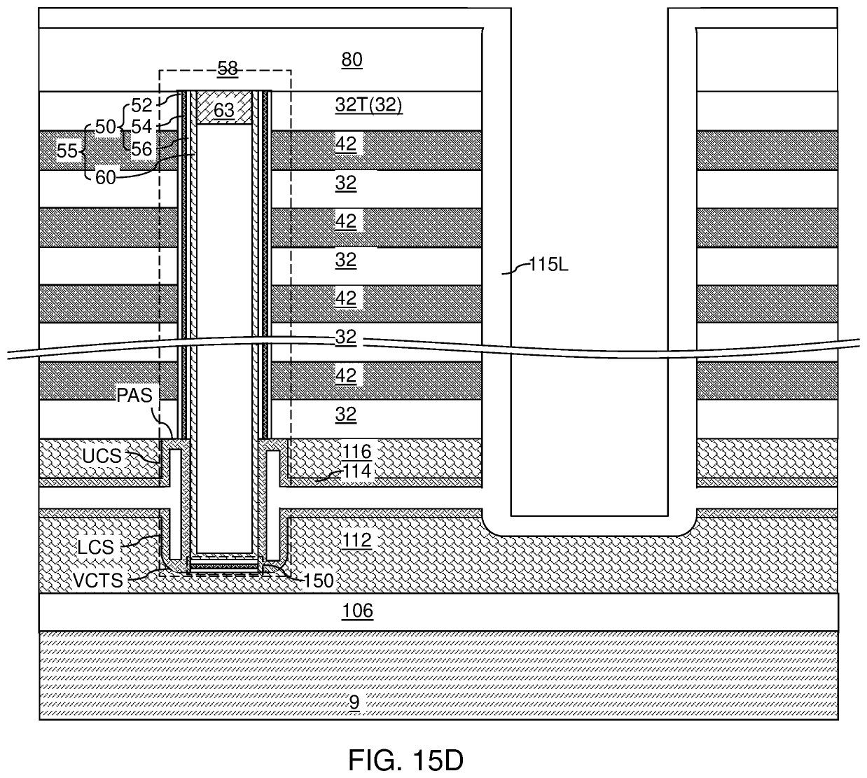

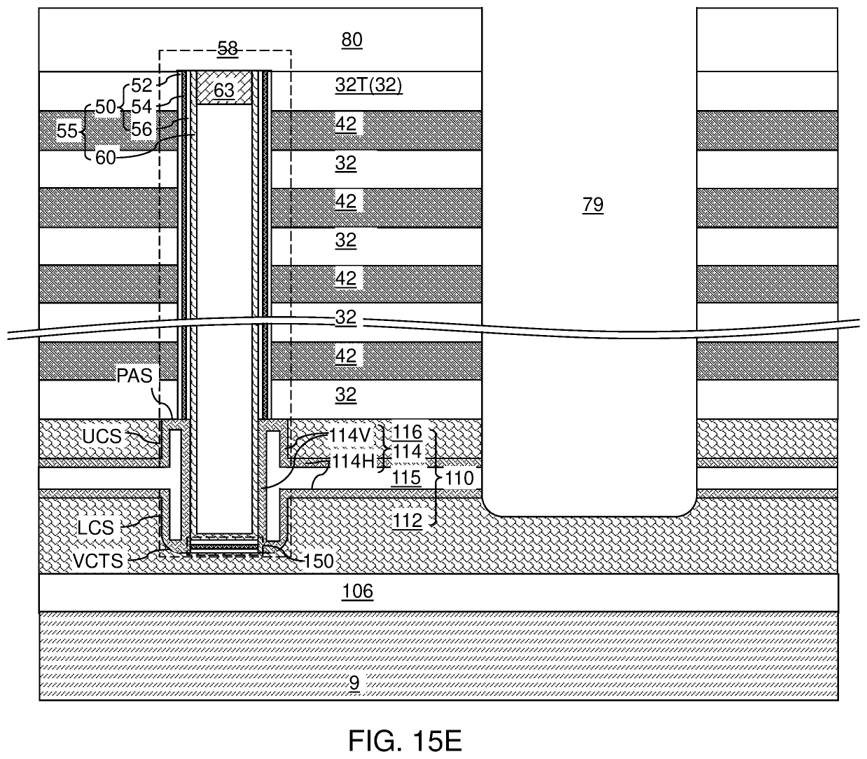

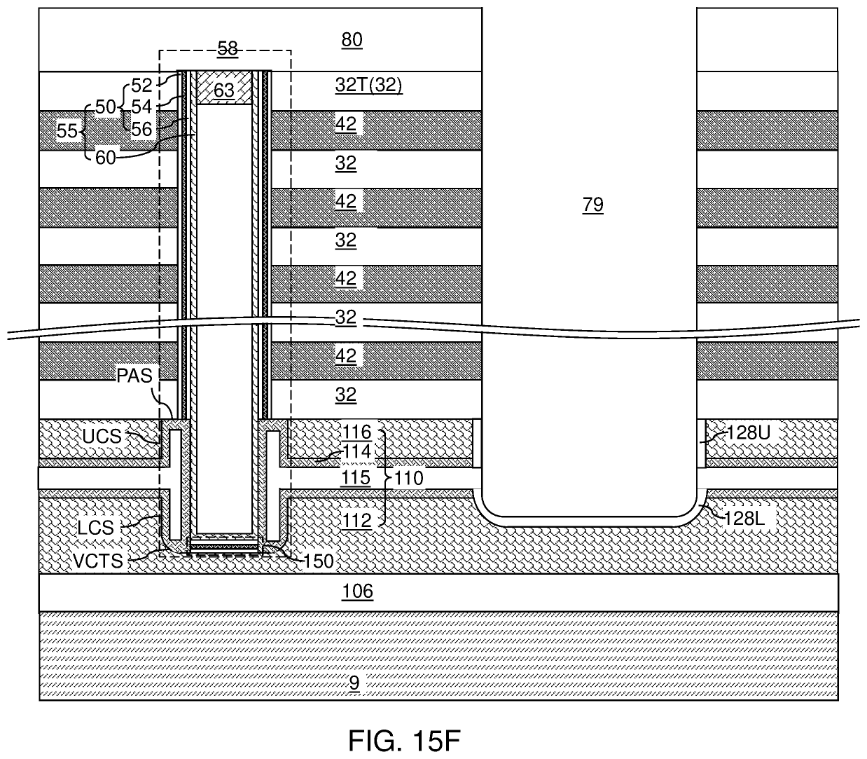

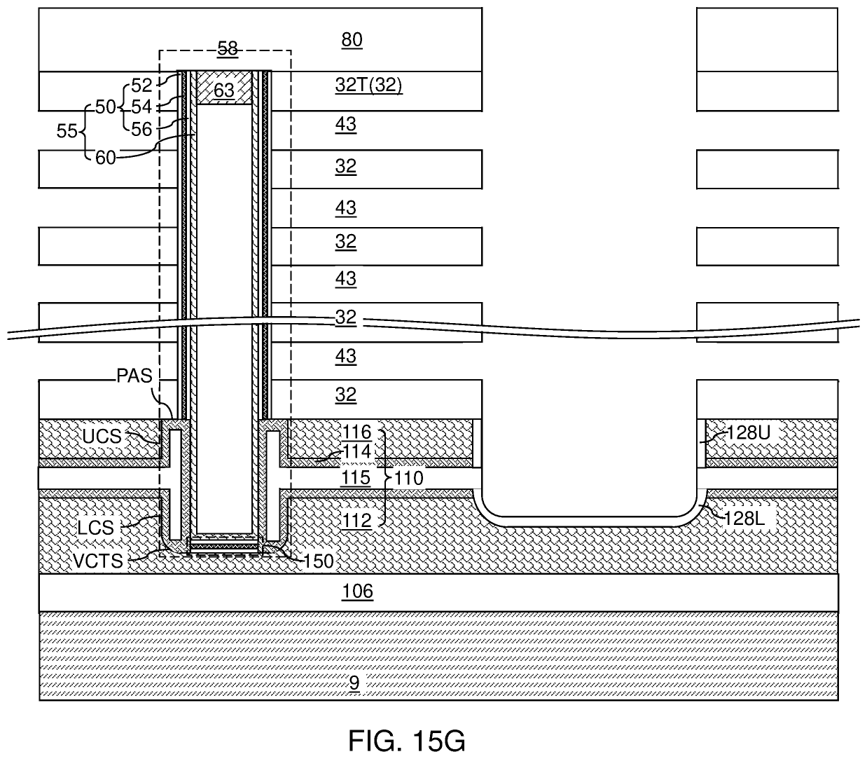

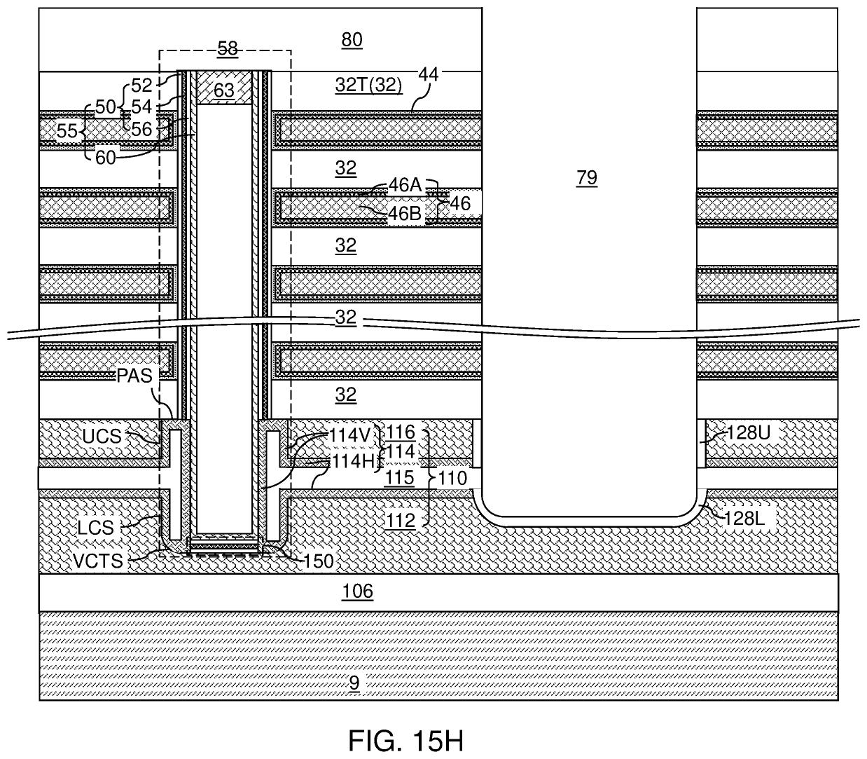

FIGS. 15A-15H are sequential vertical cross-sectional views of a region of the first exemplary structure during replacement of a source-level sacrificial layer with a source contact layer 114 and a source-level dielectric fill layer and replacement of the sacrificial material layers 42 with electrically conductive layers 46 according to the first embodiment of the present disclosure.

Referring to FIG. 15A, a sequence of isotropic etch processes may be performed, in which a sequence of isotropic etchants, such as wet etchants, is applied to the physically exposed portions of the memory films 50 to sequentially etch the various component layers of the memory films 50 from outside to inside, and to physically expose cylindrical surfaces of the vertical semiconductor channels 60 at the level of the source cavity 109. The upper sacrificial liner 105 (if present) and the lower sacrificial liner 103 (if present) may be collaterally etched during removal of the portions of the memory films 50 located at the level of the source cavity 109.

The annular cavities (591, 592) are connected to and are incorporated into the source cavity 109 upon removal of the upper sacrificial liner 105 and the lower sacrificial liner 103. Thus, the portions of the memory films 50 that are removed during the sequence of isotropic etch processes have a vertical extent that extends at least from the horizontal plane including the topmost boundaries of the first annular cavities 591 and at least to the horizontal plane including the bottommost boundaries of the second annular cavities 592. In one embodiment, the portions of the memory films 50 that are removed during the sequence of isotropic etch processes have a vertical extent that extends at least from the horizontal plane including the bottommost surfaces of the alternating stacks (32, 42) and at least to the horizontal plane including the bottommost boundaries of the second annular cavities 592.

The source cavity 109 may be expanded in volume by removal of the portions of the memory films 50 at the level of the source cavity 109 and the upper and lower sacrificial liners (105, 103). Bottom surfaces of the bottommost insulating layers 32B, sidewalls of the upper source-level semiconductor layer 116, and sidewalls of the lower source-level semiconductor layer 112 may be physically exposed to the source cavity 109. As described above, the source cavity 109 is formed by isotropically etching the source-level sacrificial layer 104 and a bottom portion of each of the memory films 50 selective to at least one source-level semiconductor layer (such as the lower source-level semiconductor layer 112 and the upper source-level semiconductor layer 116) and the vertical semiconductor channels 60.

Each remaining portion of a memory film 50 that remains under the bottom portion of a respective vertical semiconductor channel 60 constitutes a dielectric layer stack 150. The dielectric layer stack 150 has a same set of materials as the memory film 50, and contacts the lower source-level semiconductor layer 112 and a bottom portion of a vertical semiconductor channel 60, and is exposed to the source cavity 109.

Referring to FIG. 15B, a semiconductor material having a doping of the second conductivity type may be deposited on the physically exposed semiconductor surfaces around the source cavity 109. The physically exposed semiconductor surfaces include bottom portions of outer sidewalls of the vertical semiconductor channels 60 and a horizontal surface of the at least one source-level semiconductor layer (such as a bottom surface of the upper source-level semiconductor layer 116 and/or a top surface of the lower source-level semiconductor layer 112). For example, the physically exposed semiconductor surfaces may include the bottom portions of outer sidewalls of the vertical semiconductor channels 60, the top horizontal surface of the lower source-level semiconductor layer 112, and the bottom surface of the upper source-level semiconductor layer 116.

In one embodiment, the doped semiconductor material of the second conductivity type may be deposited on the physically exposed semiconductor surfaces around the source cavity 109 by a selective semiconductor deposition process or by a non-selective conformal semiconductor deposition process. The deposited doped semiconductor material forms a source contact material layer 114L, which may contact sidewalls of the vertical semiconductor channels 60. The atomic concentration of the dopants of the second conductivity type in the deposited semiconductor material may be in a range from 1×10¹⁸/cm³ to 2×10²¹/cm³, such as from 5×10²⁰/cm³ to 1×10²¹/cm³. In one embodiment, the source contact material layer 114L may be formed as a conformal doped semiconductor layer, and may have a thickness that is less than one half of the thickness of the source cavity 109. In this case, a laterally-extending void may be present within the volume of the source cavity 109 after formation of the source contact material layer 114L.

In one embodiment, the source contact material layer 114L may comprise a phosphorus doped polysilicon layer. Since the phosphorus doped polysilicon layer 114L extends vertically into the first annular cavity 591, it is located closer to the bottom of the alternating stack (32, 42) than if the first annular cavity 591 was omitted. During a subsequent annealing step, the n-type phosphorus dopant diffuses upward into the bottom part of the intrinsic or p-type vertical semiconductor channel 60. This phosphorus outdiffusion forms a vertical n-type source region at the source select gate electrode levels of the alternating stack (32, 42). Therefore, the phosphorus vertical diffusion length into the bottom of the vertical semiconductor channel 60 is reduced due to the presence of the first annular cavity 591. This in turn reduces the likelihood of select gate level cut off failure and improves memory device erasing by gate induced leakage (e.g., by hole injection from the bottom of the device).

Referring to FIG. 15C, an anisotropic etch back process with an isotropic etch component can be performed to remove portions of the source contact material layer 114L from above the contact-level dielectric layer 80 and from the peripheral portions of the lateral isolation trenches 79. The second sacrificial spacer layer 712, which may comprise a semiconductor material such as silicon, can be collaterally removed during the anisotropic etch back process. The remaining portion of the source contact material layer 114L that remains in the source cavity 109 constitutes a source contact layer 114.

Referring to FIG. 15D, the first sacrificial spacer layer 711 may optionally be removed by selective etching, such as by dilute hydrofluoric acid etching. An insulating fill material, such as silicon oxide, may be conformally deposited in the laterally-extending void in the volume of the source cavity 109 to form an insulating fill material layer 115L. The combination of the source contact layer 114 and the insulating fill material layer 115L can fill the source cavity 109.

Referring to FIG. 15E, at least one etch back process can be performed to remove potions of insulating fill material layer 115L located above the contact-level dielectric layer 80 and inside the lateral isolation trenches 79. The at least one etch back process may comprise an isotropic etch process such as a wet etch process. The remaining portion of the insulating fill material layer 115L constitutes a source-level insulating fill material layer 115. In one embodiment, a sidewall of a source-level insulating fill material layer 115 may be vertically coincident with an overlying sidewall and an underlying sidewall of a source contact layer 114 around a bottom portion of a respective lateral isolation trench 79.

Thus, the source-level sacrificial layer 104 is replaced with at least a source contact layer 114 by providing an etchant that etches the source-level sacrificial layer 104 through the lateral isolation trenches 79 and by providing a reactant that deposits the source contact layer 114 through the lateral isolation trench 79. The combination of the lower source-level semiconductor layer 112, the source contact layer 114, the optional source-level insulating fill material layer 115, and the upper source-level semiconductor layer 116 constitutes source-level material layers 110. In one embodiment, the source-level insulating fill material layer 115 is surrounded by the source contact layer 114. A p-n junction can be formed at each interface between the source contact layer 114 and the vertical semiconductor channel 60.

In summary, at least the source-level sacrificial layer 104, the first annular cavity fill structures 511, and the second annular cavity fill structures 512 are replaced with at least one replacement material layer (114, 115) comprising the source contact layer 114 and the optional source-level insulating fill material layer 115. The source contact layer 114 is formed directly on a lower portion of an outer sidewall of each vertical semiconductor channel 60. A portion of the at least one replacement material layer (114, 115) replaces and is formed in the volume of the first annular cavity fill structures 511 and the second annular cavity fill structures 512.

In one embodiment, the source contact layer 114 comprises a horizontally-extending portion 114H having a uniform thickness and vertically-extending portions 114V that are formed around a respective one of the memory opening fill structures 58. Each vertically-extending portion of the source contact layer 114V has a greater vertical extent than the horizontally-extending portion 114H, has an inner cylindrical sidewall contacting a bottom portion of a respective vertical semiconductor channel 60, and contacts a bottommost insulating layer 32B within the alternating stack (32, 42).

In one embodiment, a contact area between a vertically-extending portion 114H of the source contact layer 114 and the bottommost insulating layer 32B comprises a horizontal planar annular surface PAS. An outer periphery of the planar annular surface PAS is laterally offset from an inner periphery of the annular shape by a uniform lateral offset distance, which is the same as the lateral distance between an inner sidewall and an outer sidewall of a vertically-extending portion 114V of the source contact layer 114. In one embodiment, the uniform lateral offset distance may be the same as the sum of the lateral recess distance (i.e., the etch distance) of the selective isotropic etch process that forms the annular cavities (149, 249) and the thickness of a memory film 50.

In one embodiment, the vertically-extending portion 114V of the source contact layer 114 comprises a respective vertical upper cylindrical sidewall UCS that overlies the horizontally-extending portion 114H and a respective lower cylindrical sidewall LCS that underlies the horizontally-extending portion 114H. In one embodiment, an upper periphery of the upper cylindrical sidewall UCS coincides with the outer periphery of the planar annular surface PAS of the same vertically-extending portion. In one embodiment, the upper cylindrical sidewall UCS and the lower cylindrical sidewall LCS of the same vertically-extending portion 114V are vertically coincident, i.e., are located within a same cylindrical vertical plane.

In one embodiment, the vertically-extending portion 114V of the source contact layer 114 may also comprise a respective vertically-convex tapered sidewall VCTS that is adjoined to a bottom periphery of the lower cylindrical sidewall LCS. As used herein, a vertically-convex surface refers to a surface having a convex vertical cross-sectional profile, i.e., having a convex profile in a vertical cross-sectional view. In one embodiment, the lateral extent of the vertically-extending portion 114V of the source contact layer 114 may decrease with a downward distance from the alternating stack (32, 42) below a horizontal plane including the bottom periphery of the lower cylindrical sidewall LCS of the vertically-extending portion 114V of the source contact layer 114.

In one embodiment, a top surface of the vertically-extending portion 114V of the source contact layer 114 may contact a bottom surface of a respective memory film 50 at or above a horizontal plane including a bottom surface of a bottommost insulating layer 32B of an overlying alternating stack (32, 42). In one embodiment, an outer cylindrical sidewall (e.g., UCS and/or LCS) of the vertically-extending portion 114V of the source contact layer 114 can be laterally offset from a respective vertical semiconductor channel 60 by a lateral offset distance that is greater than the thickness of the memory film 50.

In one embodiment, the source-level material layers 110 comprise a source-level insulating fill material layer 115 that is embedded within the source contact layer 114. In one embodiment, the source contact layer 114 has a uniform thickness that is less than one half of a lateral spacing between the upper source-level semiconductor layer 116 and each of the vertical semiconductor channels 60. In one embodiment, the memory opening fill structure 58 comprises a dielectric layer stack 150 underlying a bottom surface of the vertical semiconductor channel 60 and having a same set of materials as the memory film 50, and the dielectric layer stack 150 contacts the lower source-level semiconductor layer 112 and the source contact layer 114. In one embodiment, the vertical semiconductor channel 60 has a doping of a first conductivity type, and the lower source-level semiconductor layer 112, the source contact layer 114, and the upper source-level semiconductor layer 116 have a doping of a second conductivity type that is an opposite of the first conductivity type.

Referring to FIG. 15F, an oxidation process may be performed to convert physically exposed surface portions of the upper source-level semiconductor layer 116, the source contact layer 114 and the lower source-level semiconductor layer 112 into dielectric semiconductor oxide liners (128U. 128L). For example, an upper dielectric semiconductor oxide liner 128U may be formed on the upper source-level semiconductor layer 116 and the upper portion of the source contact layer 114, while a lower dielectric semiconductor oxide liner 128L may be formed on the lower portion of the source contact layer 114 and the lower source-level semiconductor layer 112.

Referring to FIG. 15G, an isotropic etch process can be performed to remove the sacrificial material layers 42 selective to the insulating layers 32, the backside insulating layer 106, the memory opening fill structures 58, the dielectric semiconductor oxide liners (128U, 128L), and the source-level insulating fill material layer 115 (if present). Laterally-extending cavities 43 can be formed in volumes from which the sacrificial material layers 42 are removed. Sidewall surface segments of the memory opening fill structures 58 (i.e., of the memory film 50) can be physically exposed to the laterally-extending cavities 43. In an illustrative example, if the sacrificial material layers 42 comprise silicon nitride, the isotropic etch process may comprise a wet etch process employing hot phosphoric acid, which is a process in which the exemplary structure is immersed in phosphoric acid at, or near, the boiling point of the phosphoric acid. A suitable cleaning process may be performed as needed.

Referring to FIG. 15H, a backside blocking dielectric layer 44 can be optionally formed in the laterally-extending cavities 43 by a conformal deposition process. At least one conductive material, such as at least one metallic material, can be conformally deposited in the laterally-extending cavities 43. The at least one conductive material may comprise, for example, a combination of a metallic barrier material 46A and a metallic fill material 46B. The metallic barrier material may comprise, for example, TiN, TaN, WN, MoN, TIC, TaC, WC, or a combination thereof. The metallic fill material may comprise, for example, Ti, Ta, Mo, Co, Ru, W, Cu, other transition metals, and/or alloys or layer stacks thereof.

Excess portions of the at least one conductive material that are deposited in the lateral isolation trenches 79 or above the contact-level dielectric layer 80 can be removed by performing an etch-back process, which may comprise an isotropic etch process and/or an anisotropic etch process. Each remaining portion of the at least one conductive material filling a respective one of the laterally-extending cavities 43 constitutes an electrically conductive layer 46. An alternating stack of insulating layers 32 and electrically conductive layers 46 can be formed between each neighboring pair of lateral isolation trenches 79 over the substrate 8. A plurality of alternating stacks of insulating layers 32 and electrically conductive layers 46 can be laterally spaced apart among one another by the lateral isolation trenches 79. Optionally, a subset of the electrically conductive layers 46 including the bottommost electrically conductive layer 46 may be employed as at least one source-select electrode (i.e., source side select gate electrode). Optionally, a subset of the electrically conductive layers 46 including the topmost electrically conductive layer 46 may be employed as at least one drain-select electrode (i.e., drain side select gate electrode). A predominant fraction of the electrically conductive layers 46 (e.g., the electrically conductive layers located between the source-select electrodes and the drain-select electrodes may be employed as word lines.

In summary, the sacrificial material layers 42 can be replaced with the electrically conductive layers 46. An alternating stack (32, 46) of insulating layers 32 and electrically conductive layers 46 can be formed over the source-level material layers 110. Memory opening 49 can vertically extend through the alternating stack (32, 46) and into the first portion of the lower source-level semiconductor layer 112. A memory opening fill structure 58 can be formed within each memory opening 49. Each memory opening fill structure 58 comprises a memory film 50 and a vertical semiconductor channel 60 that contacts the source contact layer 114.

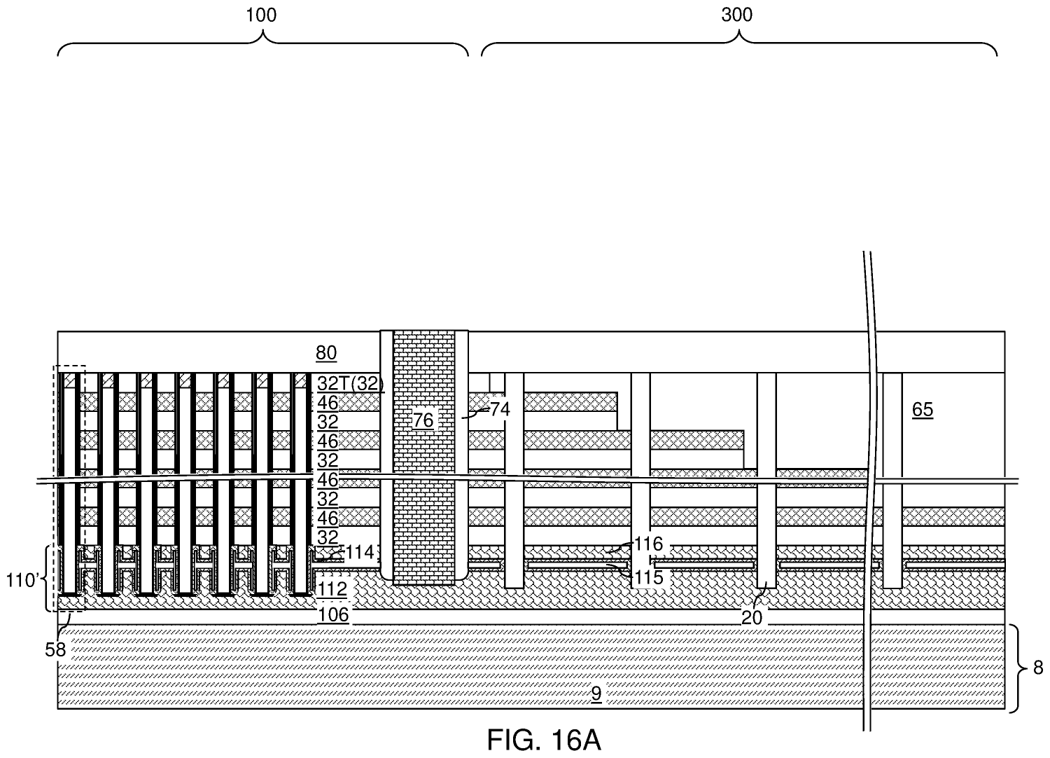

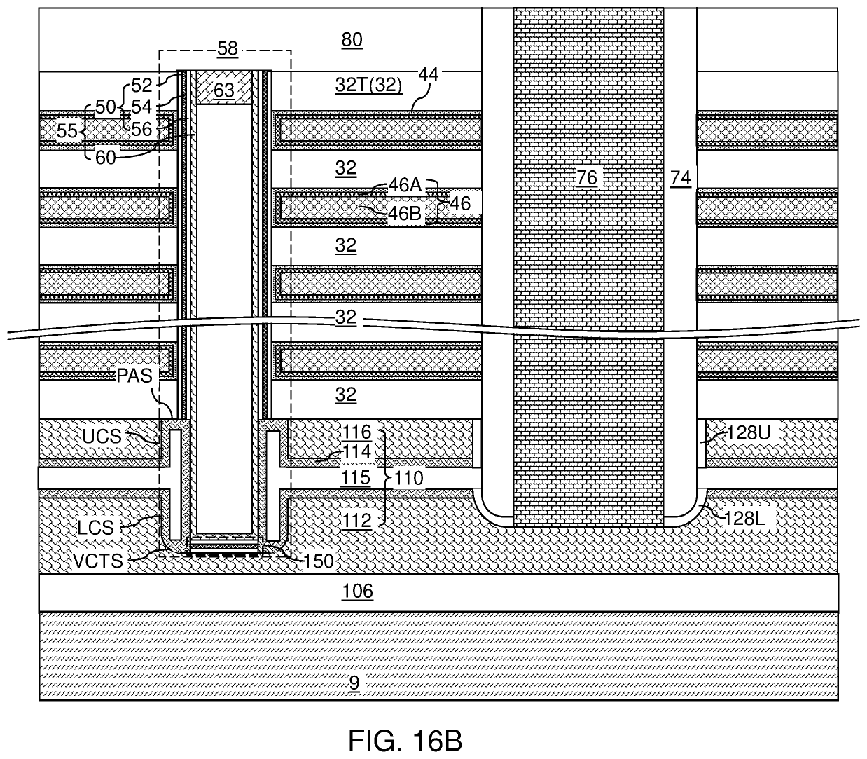

Referring to FIGS. 16A and 16B, an insulating material, such as silicon oxide, can be conformally deposited in the peripheral portions of the lateral isolation trenches 79 and above the contact-level dielectric layer 80. An anisotropic etch process can be performed to remove horizontally-extending portions of the deposited insulating material. Each remaining vertically-extending portion of the deposited insulating material constitutes an insulating spacer 74.

At least one conductive material, such as at least one metallic material, can be deposited in remaining volumes of the lateral isolation trenches 79. Excess portions of the at least one conductive material can be removed from above the horizontal plane including the top surface of the contact-level dielectric layer 80 by a planarization process such as a chemical mechanical polishing process. Each remaining portion of the at least one conductive material constitutes a contact via structure, which is herein referred to as a source contact via structure 76. Each source contact via structure 76 can contact a surface of the lower source-level semiconductor layer 112.

In summary, an insulating spacer 74 can be formed in a peripheral region of the lateral isolation trench 79. A source contact via structure 76 can be formed in a volume that is laterally surrounded by the insulating spacer 74 on a surface of the lower source-level semiconductor layer 112. If a source-level insulating fill material layer 115 is present, the source-level insulating fill material layer 115 may contact a surface segment of an outer sidewall of the insulating spacer 74.

Each contiguous combination of an insulating spacer 74 and a source contact via structure 76 constitutes a lateral isolation trench fill structure (74, 76). In an alternative embodiment, the entirety of each lateral isolation trench 79 may be filled with an insulating fill material that constitutes a lateral isolation trench fill structure, which consists essentially of the insulating fill material. Generally, each lateral isolation trench fill structure has an insulating sidewall (which may be an outer sidewall of an insulating spacer 74 or a sidewall of an insulating fill material portion) that contacts sidewalls of the insulating layers 32 and sidewalls of the electrically conductive layers 46.

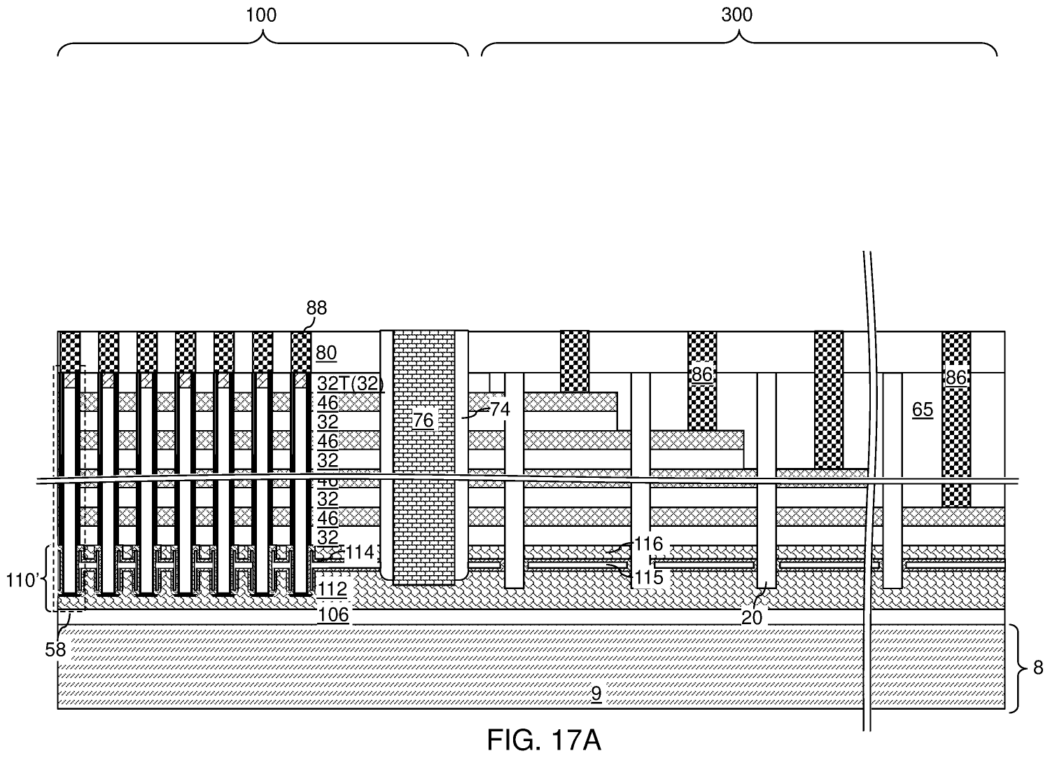

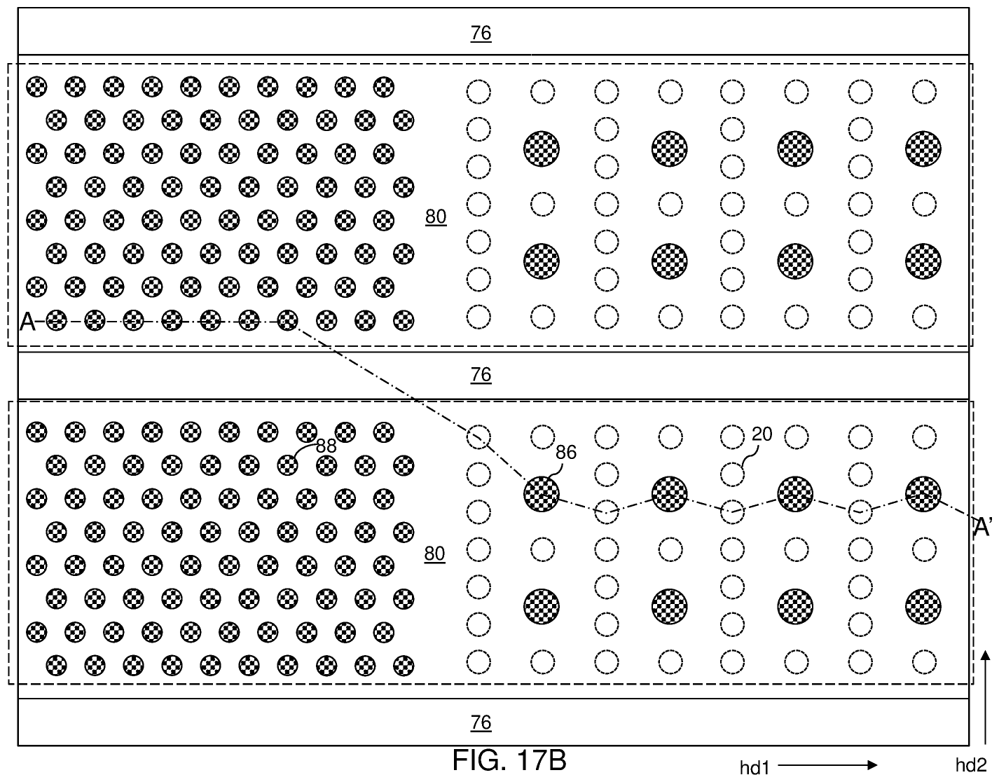

Referring to FIGS. 17A and 17B, a photoresist layer (not shown) can be applied over the contact-level dielectric layer 80, and can be lithographically patterned to form openings over each of the memory opening fill structures 58 over the horizontally-extending surfaces of the stepped surfaces in the contact region. An anisotropic etch process can be performed to transfer the pattern of the openings in the photoresist layer through the contact-level dielectric layer 80 and the retro-stepped dielectric material portion 65. Drain contact via cavities can be formed through the contact-level dielectric layer 80 over the memory opening fill structures 58. Layer contact via structures can be formed through the contact-level dielectric layer 80 and the retro-stepped dielectric material portion 65 on a top surface of a respective one of the electrically conductive layers 46. The photoresist layer can be subsequently removed, for example, by ashing.

At least one conductive material, such as a combination of a metallic barrier material and a metallic fill material, can be deposited in the drain contact via cavities and the layer contact via cavities. Excess portions of the at least one conductive material can be removed from above the horizontal plane including the top surface of the contact-level dielectric layer 80 by a planarization process, which may employ a recess etch process and/or a chemical mechanical polishing process. Remaining portions of the at least one conductive material that fill the drain contact via cavities constitute drain contact via structures 88 contacting a top surface of a respective one of the drain regions 63. Remaining portions of the at least one conductive material that fill the layer contact via cavities constitute layer contact via structures 86 contacting a top surface of a respective one of the electrically conductive layers 46.

In one embodiment, each memory opening fill structure 58 comprises a drain region 63; and a drain contact via structure 88 contacts a top surface of the drain region 63. In one embodiment, each of the electrically conductive layers 46 is contacted by a respective layer contact via structure 86 having a respective top surface located above a horizontal plane including a topmost surface of the alternating stack (32, 46).

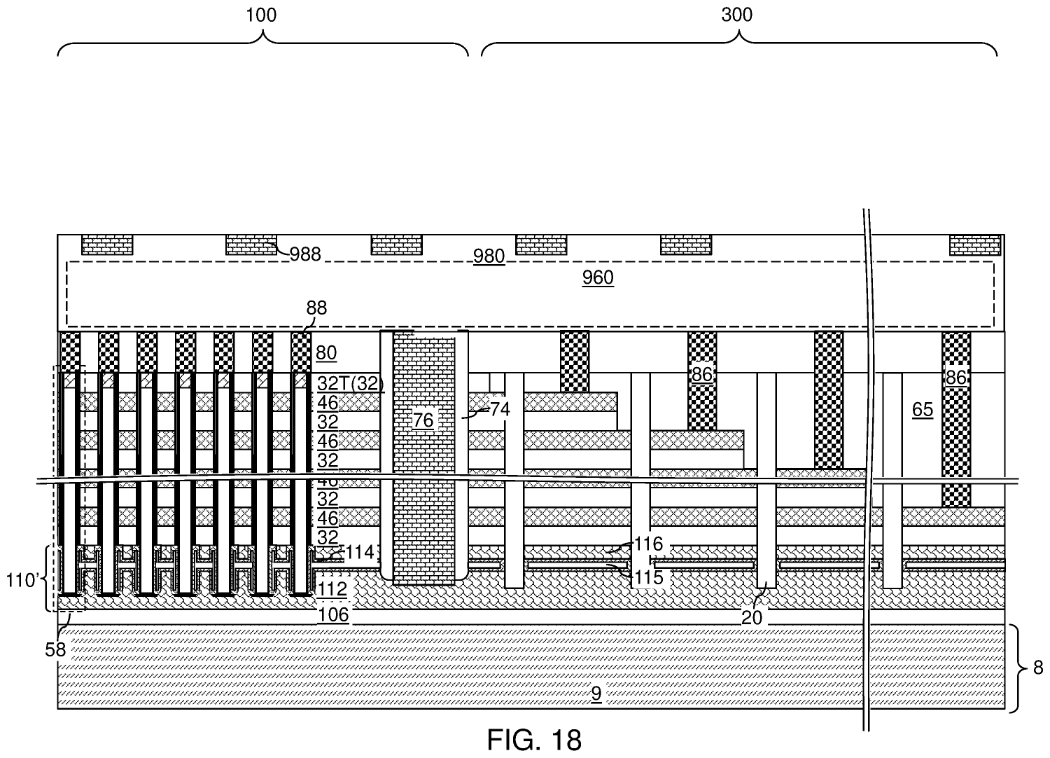

Referring to FIG. 18, additional dielectric material layers and additional metal interconnect structures can be formed over the contact-level dielectric layer 80. The additional dielectric material layers may include a bit-line-level dielectric layer (which is a line-level dielectric layer), at least one via-level dielectric layer, at least one additional line-level dielectric layer, and/or at least one additional line-and-via-level dielectric layer. The additional metal interconnect structures may comprise bit lines (which are metal lines), metal via structures, additional metal line structures, and/or integrated metal line-and-via structures. The additional dielectric material layers that are formed above the contact-level dielectric layer 80 are herein referred to as memory-side dielectric material layers 960. The additional metal interconnect structures are collectively referred to as memory-side dielectric material layers 960. The memory-side dielectric material layers 960 comprise a bit-line-level dielectric material layer embedding the bit lines, which are a subset of the memory-side metal interconnect structures 980.

Metal bonding pads, which are herein referred to as memory-side bonding pads 988, may be formed at the topmost level of the memory-side dielectric material layers 960. The memory-side bonding pads 988 may be electrically connected to the memory-side metal interconnect structures 980 and various nodes of the three-dimensional memory array including the alternating stacks of insulating layers 32 and electrically conductive layers 46 and the memory opening fill structures 58. A memory die 900 can thus be provided.

The memory-side dielectric material layers 960 are formed over the alternating stacks (32, 46). The memory-side metal interconnect structures 980 are embedded in the memory-side dielectric material layers 960. The memory-side bonding pads 988 can be embedded within the memory-side dielectric material layers 960, and specifically, within the topmost layer among the memory-side dielectric material layers 960. The memory-side bonding pads 988 can be electrically connected to the memory-side metal interconnect structures 980.

In one embodiment, the memory die 900 may comprise: a three-dimensional memory array comprising an alternating stack (32, 46) of insulating layers 32 and electrically conductive layers 46, a two-dimensional array of memory openings 49 vertically extending through the alternating stack (32, 46), and a two-dimensional array of memory opening fill structures 58 located in the two-dimensional array of memory openings 49 and comprising a respective vertical stack of memory elements and a respective vertical semiconductor channel 60; a two-dimensional array of drain contact via structures 88 electrically connected to a respective one of the vertical semiconductor channels 60; and a two-dimensional array of layer contact via structures 86 electrically connected to a respective one of the electrically conductive layers 46, a subset of which functions as word lines for the three-dimensional memory array.

In summary, a memory die 900 is provided, which comprises a memory array, memory-side metal interconnect structures 980, and memory-side bonding pads 988 embedded within memory-side dielectric material layers 960. The memory die 900 comprises a memory device, which may comprise a three-dimensional memory array including an alternating stack of insulating layers 32 and electrically conductive layers 46, and further comprises a two-dimensional array of NAND strings (e.g., the memory opening fill structures 58) vertically extending through the alternating stack (32, 46). In one embodiment, the electrically conductive layers 46 comprise word lines of the two-dimensional array of NAND strings. In one embodiment, the memory-side metal interconnect structures 980 comprise the bit lines 128 for the two-dimensional array of NAND strings.

Referring to FIG. 19, an optional logic die 700 is provided. If there is no peripheral circuit located on the substrate 8, then the logic die 700 includes the peripheral circuit 720 that is formed on a logic-side substrate 709. According to an aspect of the present disclosure, the peripheral circuit 720 can be configured to control operation of the memory array within the memory die 900. For example, the peripheral circuit 720 may comprise word line driver regions, bit line driver regions, sense amplifier regions, input/output buffer regions, etc. Logic-side metal interconnect structures 780 embedded within logic-side dielectric material layers 760 can be formed over the peripheral circuit 720. The logic die 700 comprises logic-side bonding pads 788 embedded within logic-side dielectric material layers 760.

Referring to FIG. 20, a bonded assembly can be formed by bonding the logic die 700 with the memory die 900. The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

The logic die 700 can be attached to the memory die 900, for example, by bonding the logic-side bonding pads 788 to the memory-side bonding pads 988. The bonding between the memory die 900 and the logic die 700 may be performed employing a wafer-to-wafer bonding process in which a two-dimensional array of memory dies 900 is bonded to a two-dimensional array of logic dies 700, by a die-to-bonding process, or by a die-to-die bonding process. The logic-side bonding pads 788 within each logic die 700 can be bonded to the memory-side bonding pads 988 within a respective memory die 900.

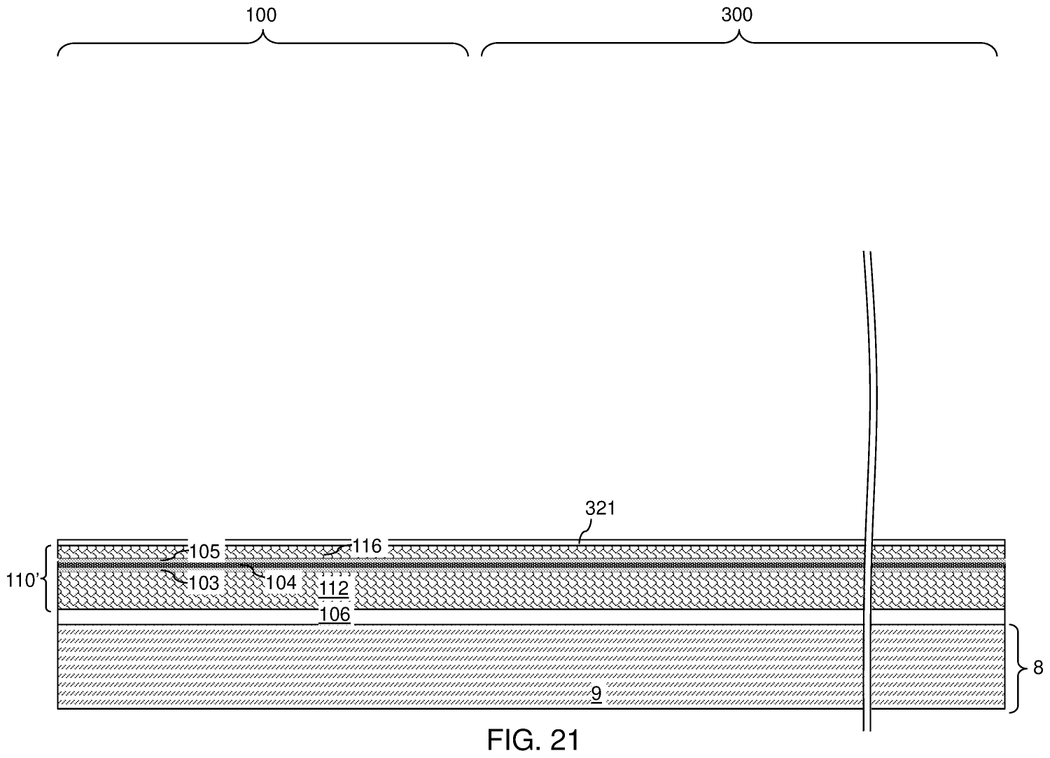

Referring to FIG. 21, a second exemplary structure can be derived from the first exemplary structure illustrated in FIG. 1 by forming an insulating liner 321 on a topmost surface of the in-process source-level material layers 110′. The insulating liner 321 may comprise the same material as the bottommost insulating layer 32B described with reference to the first exemplary structure, and may have a thickness in a range from 3 nm to 30 nm, although lesser and greater thicknesses may also be employed.

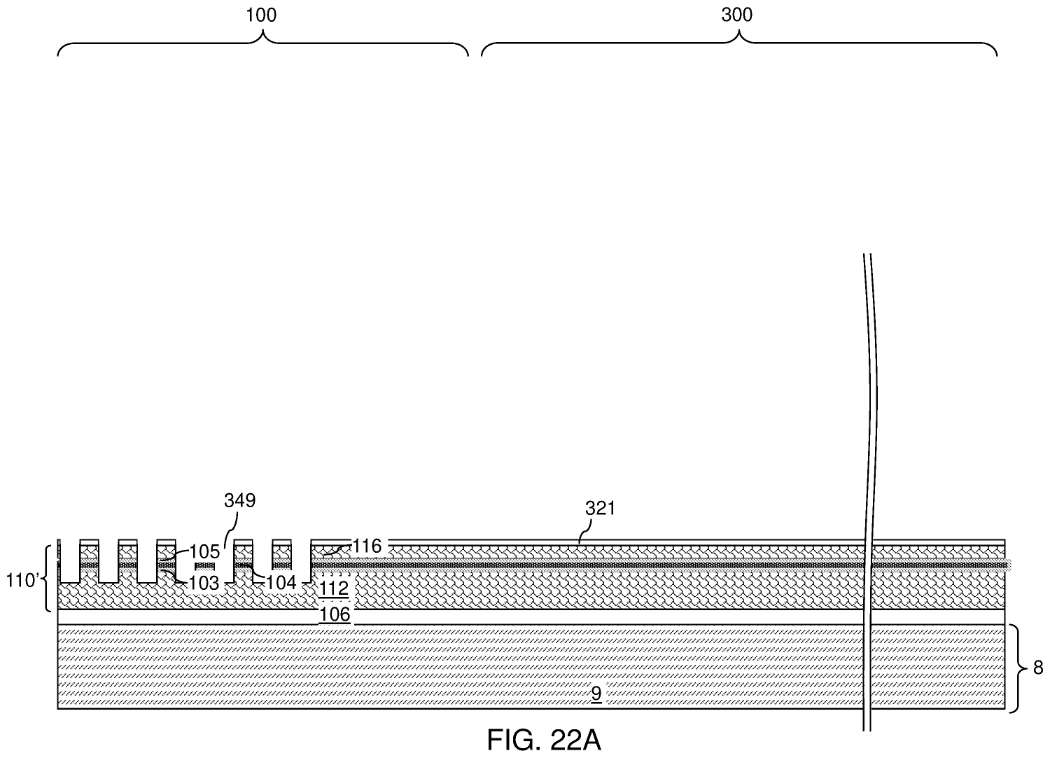

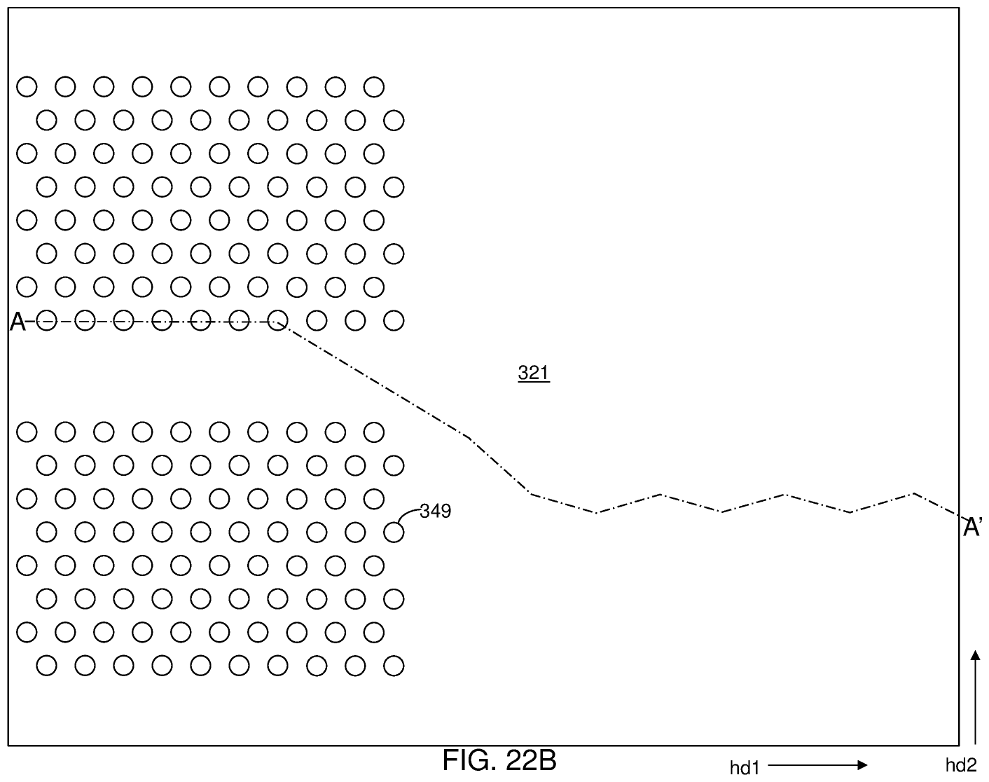

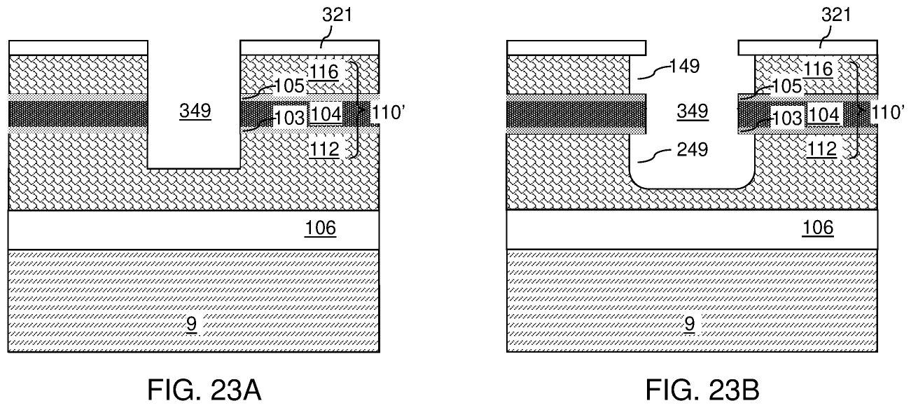

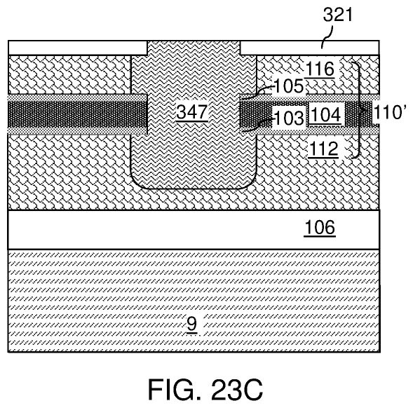

Referring to FIGS. 22A, 22B, and 23A, a photoresist layer (not shown) can be applied over the insulating liner 321, and can be lithographically patterned with a pattern of discrete openings. The pattern of the discrete openings may be the same as the pattern of the memory openings 49 that are formed in the first exemplary structure. An anisotropic etch process can be performed to transfer the pattern of the openings in the photoresist layer through the insulating liner 321, the upper source-level semiconductor layer 116, the optional upper sacrificial liner 105, the source-level sacrificial layer 104, the optional lower sacrificial liner 103, and an upper portion of the lower source-level semiconductor layer 112.

Arrays of discrete source-level openings 349 may be formed through the insulating liner 321 and in the in-process source-level material layers 110′. The pattern of the discrete source-level openings 349 in the second exemplary structure may be the same as the pattern of the portion of the memory openings 49 in the in-process source-level material layers 110′ in the first exemplary structure.

Referring to FIG. 23B, the processing seps described with reference to FIG. 8B may be performed to form the first annular cavity 149 and the second annular cavity 249 around each discrete source-level opening 349. Specifically, a selective isotropic etch process can be performed to isotropically recess the upper source-level semiconductor layer 116 and the lower source-level semiconductor layer 112 selective to the insulating liner 321 and the source-level sacrificial layer 104. For example, a wet etch process using hot trimethyl-2 hydroxyethyl ammonium hydroxide (“hot TMY”) or tetramethyl ammonium hydroxide (TMAH) may be performed to isotropically recess the upper source-level semiconductor layer 116 and the lower source-level semiconductor layer 112 selective to the material of the insulating liner 321 and the source-level sacrificial layer 104.

Referring to FIG. 23C, a sacrificial fill material that can be removed selective to the materials of the in-process source-level material layers 110′ can be deposited in the discrete source-level openings 349. For example, the sacrificial fill material may comprise a polymer material, porous or non-porous organosilicate glass, a silicate glass having a high etch rate, such as borosilicate glass, a carbon-based material (such as amorphous carbon or diamond-like carbon) that may be subsequently removed by ashing, or any other suitable fill material that may be subsequently removed selective to the materials of the in-process source-level material layers 110′ and selective to the materials of an alternating stack (32, 42) to be subsequently formed as in the manufacture of the first exemplary structure described above. Excess portions of the sacrificial fill material can be removed from above the horizontal plane including the top surface of the insulating liner 321 by performing a planarization process. For example, the planarization process may comprise a chemical mechanical polishing process or a recess etch process. Each remaining portion of the sacrificial fill material constitutes a sacrificial pedestal structure 347. In one embodiment, top surfaces of the sacrificial pedestal structures 347 may be formed at or in proximity to a horizontal plane including the top surface of the insulating liner 321.

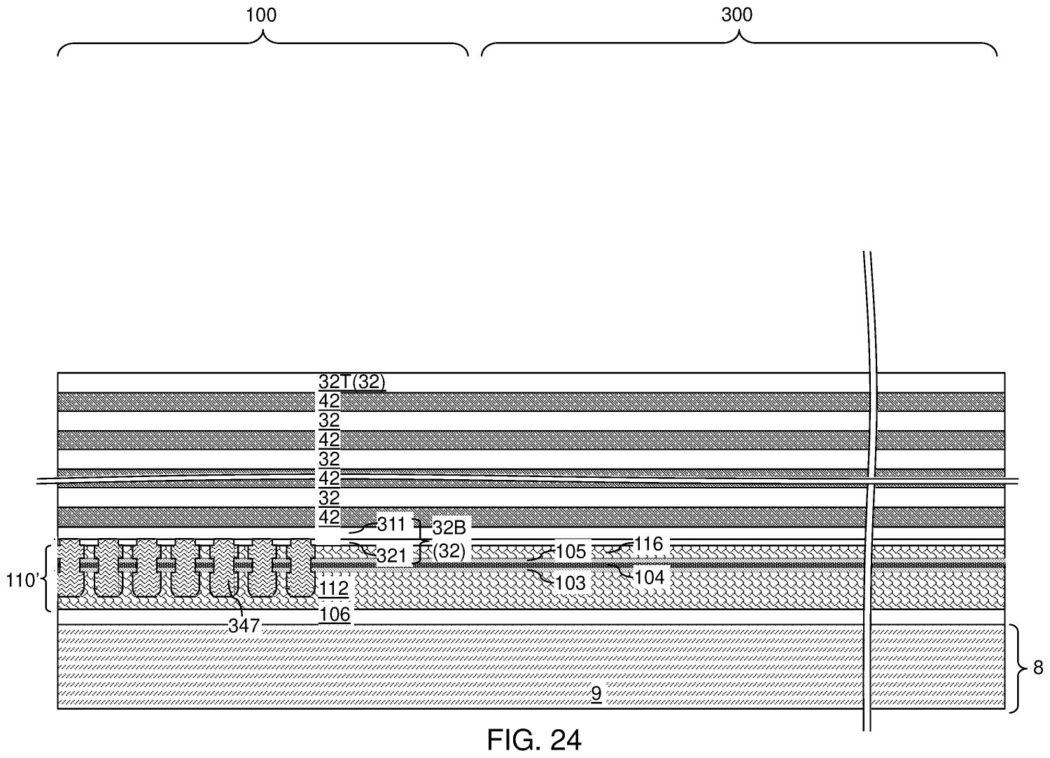

Referring to FIG. 24, the processing steps described with reference to FIG. 2 can be performed to form an alternating stack of insulating layers 32 and sacrificial material layers 42. The first layer that is deposited over the insulating liner 321 is herein referred to as a complementary insulating layer 311. The complementary insulating layer 311 may have the same material composition as the insulating liner 321, and the sum of the thicknesses of the insulating liner 321 and the complementary insulating layer 311 may be the same as the thickness of the bottommost insulating layer 32B described with reference to the first exemplary structure. Generally, the alternating stack (32, 42) formed in the second exemplary structure may be the same as the alternating stack (32, 42) formed in the first exemplary structure.

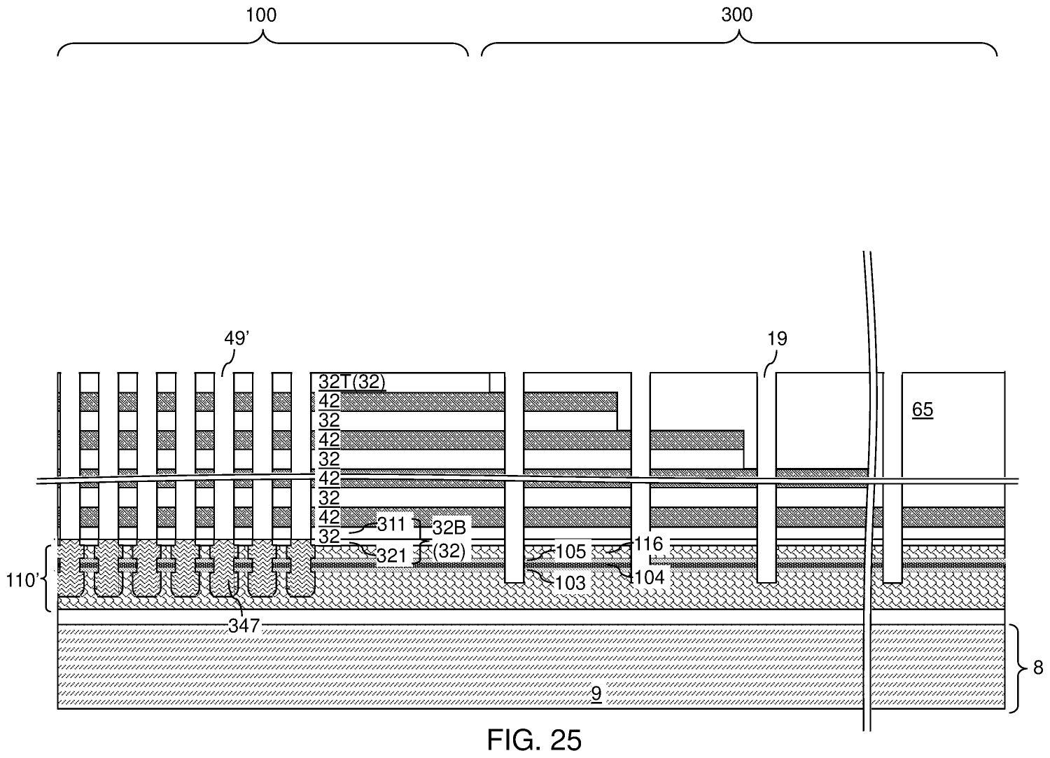

Referring to FIG. 25, the processing steps described with reference to FIGS. 3, 4A, and 4B can be performed to form the stepped surfaces, the retro-stepped dielectric material portion 65, cylindrical cavities 49′, and support openings 19. Each cylindrical cavity 49′ can be formed over a respective one of the sacrificial pedestal structures 347. A top surface of a sacrificial pedestal structure 347 is exposed underneath each cylindrical cavity 49′. The arrays of cylindrical cavities 49′ may have the same pattern as the arrays of sacrificial pedestal structures 347. In some embodiments, top portions of the sacrificial pedestal structures 347 may be collaterally removed during formation of the cylindrical cavities 49′.

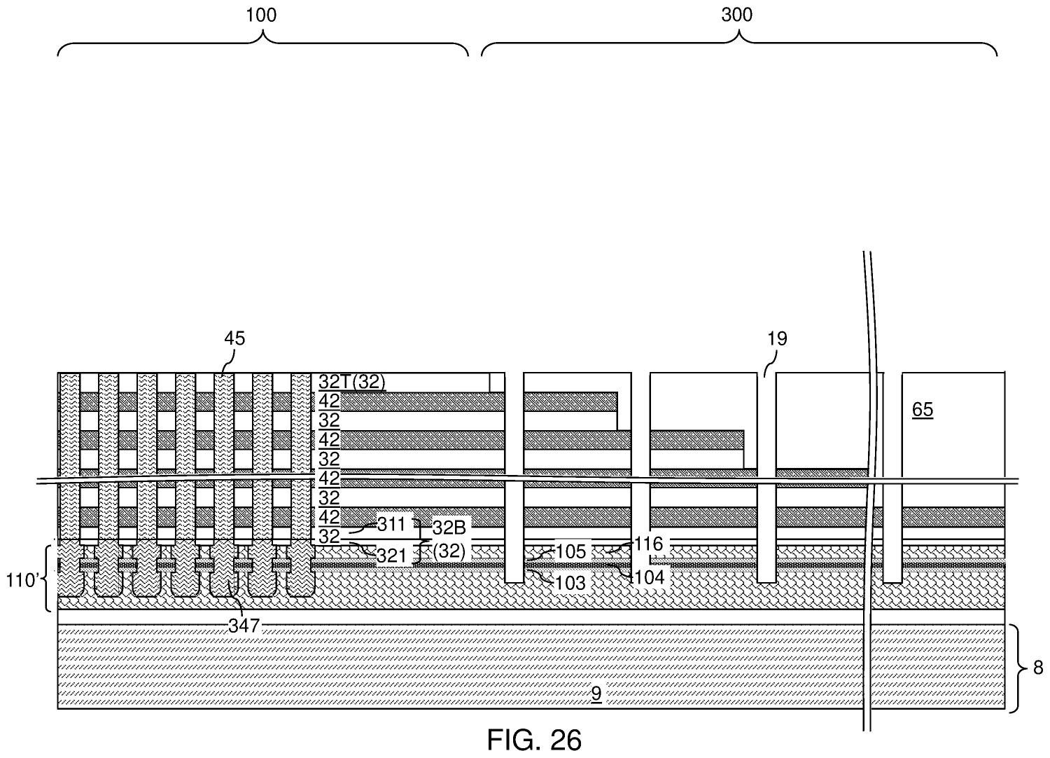

Referring to FIG. 26, the processing steps described with reference to FIG. 5 can be performed to form sacrificial memory opening fill structures 45 in the cylindrical cavities 49′ and to form sacrificial support opening fill structures (not shown) in the support openings 19. Subsequently, the sacrificial support opening fill structures may be removed from inside the support openings 19 without removing the sacrificial memory opening fill structures 45.

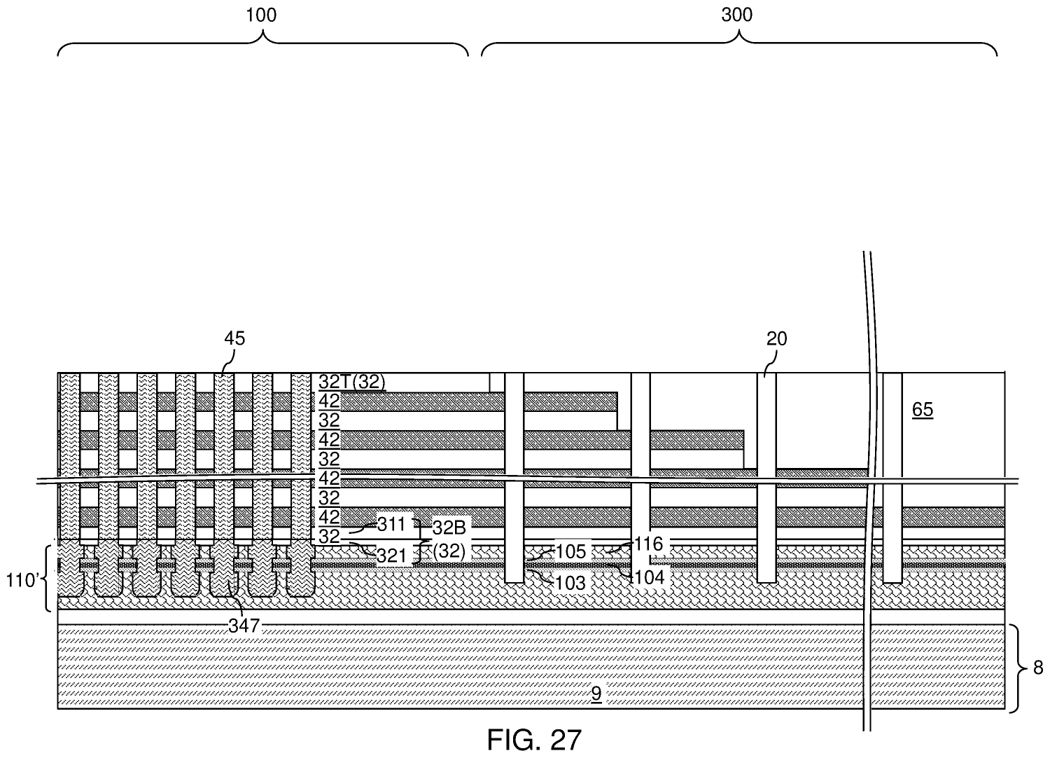

Referring to FIG. 27, the processing steps described with reference to FIG. 6 can be performed to form support pillar structures 20 in the support openings 19.

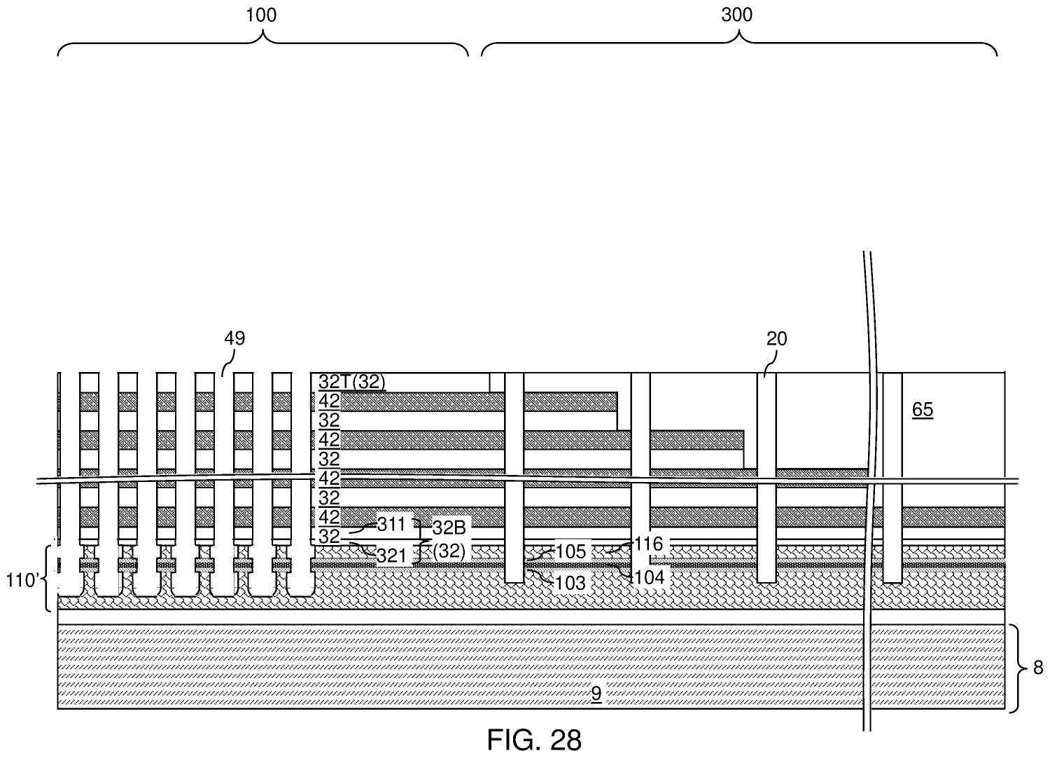

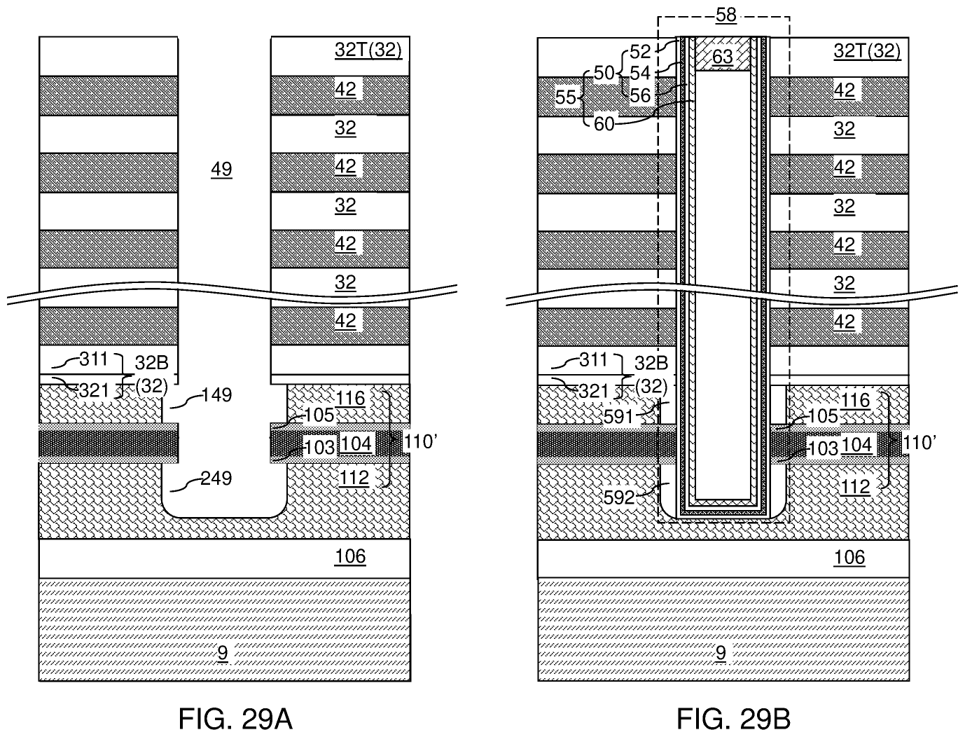

Referring to FIGS. 28 and 29A, the sacrificial memory opening fill structures 45 can be removed selective to the alternating stack (32, 42), the retro-stepped dielectric material portion 65, and the support pillar structures to form cavities in the volumes of the sacrificial memory opening fill structures 45. Subsequently or concurrently, the sacrificial pedestal structures 347 can be removed selective to the materials of the alternating stack (32, 42) and the in-process source-level material layers 110′. Memory openings 49 are formed in the volumes from which the sacrificial memory opening fill structures 45 and the sacrificial pedestal structures 347 are removed. As such, the volumes of the memory openings 49 may include the volumes of the discrete source-level openings 349 (which include volumes of the annular cavities (149, 249) formed at the processing steps of FIG. 23B) and the volumes of the cylindrical cavities 49′ as formed at the processing steps of FIG. 25. In other words, the memory openings 49 are formed upon removal of the sacrificial pedestal structures 347 from underneath the volumes of the cylindrical cavities 49′.

Each of the memory openings 49 comprises a first annular cavity 149 located at a level of the upper source-level semiconductor layer 116 and undercutting the alternating stack (32, 42). The second exemplary structure illustrated in FIGS. 28 and 29A may be the same as the first exemplary structure illustrated in FIG. 8B, or may be derived from the first exemplary structure illustrated in FIG. 8B by introducing a lateral shift between portions of the memory openings 49 overlying the horizontal plane including the interface between the alternating stack (32, 42) and the in-process source-level material layers 110′ and portions of the memory opening 49 underlying the horizontal plane. Such a lateral shift corresponds to the overlay error introduced during the lithographic patterning step that defines the pattern of the cylindrical cavities 49′ at the processing steps of FIG. 25 with respect to the pattern of the sacrificial pedestal structures 347. Generally, the magnitude of the lateral shift, i.e., the overlay error, may be in a range from 0.1% to 30% of the lateral dimension (such as a diameter) of each cylindrical cavity 49′.

Referring to FIG. 29B, the processing steps described with reference to FIGS. 8C-8H can be performed to form a memory opening fill structure 58 in each memory opening 49. The second exemplary structure at the processing steps of FIG. 29B may be the same as the first exemplary structure at the processing steps of FIGS. 8H, 9A, and 9B, or may be derived therefrom by off-centering the annular cavities (591, 592) with respect to the memory opening fill structures 58 (due to overlay errors between the pattern of the cylindrical cavities 49′ and the pattern of the sacrificial pedestal structures 347 as discussed above).

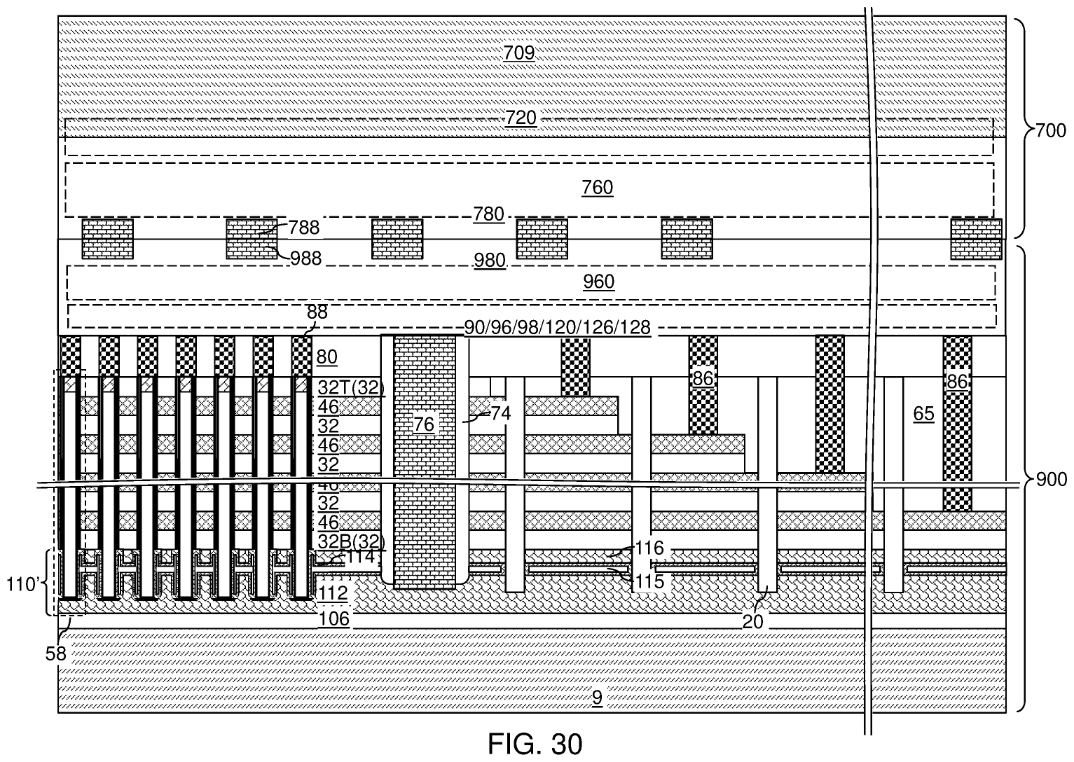

Referring to FIG. 30, the processing steps described with reference to FIGS. 10A-20 can be performed to form additional device components. The second exemplary structure of FIG. 30 may be the same as the first exemplary structure of FIG. 20. Generally, at least the source-level sacrificial layer 104, the first annular cavity fill structures 511, and the second annular cavity fill structures 512 can be replaced with at least one replacement material layer (114, 115) comprising a source contact layer 114. The source contact layer 114 is formed directly on a lower portion of an outer sidewall of vertical semiconductor channels 60.

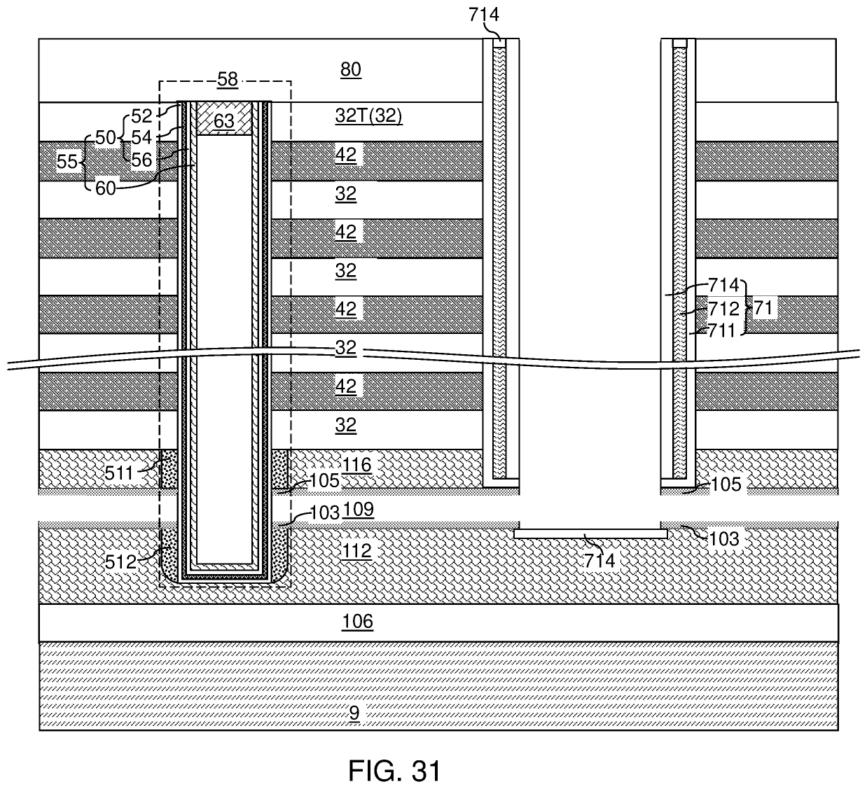

Referring to FIG. 31, a third exemplary structure is illustrated at a processing step that corresponds to the processing step illustrated in FIGS. 14A and 14B. The third exemplary structure can be derived from the first exemplary structure or the second exemplary structure by omitting removal of the processing steps described with reference to FIG. 8F. In this case, the first annular cavity fill structures 511 and the second annular cavity fill structures 512 are present after the processing step that corresponds to the processing steps described with reference to FIGS. 14A and 14B.

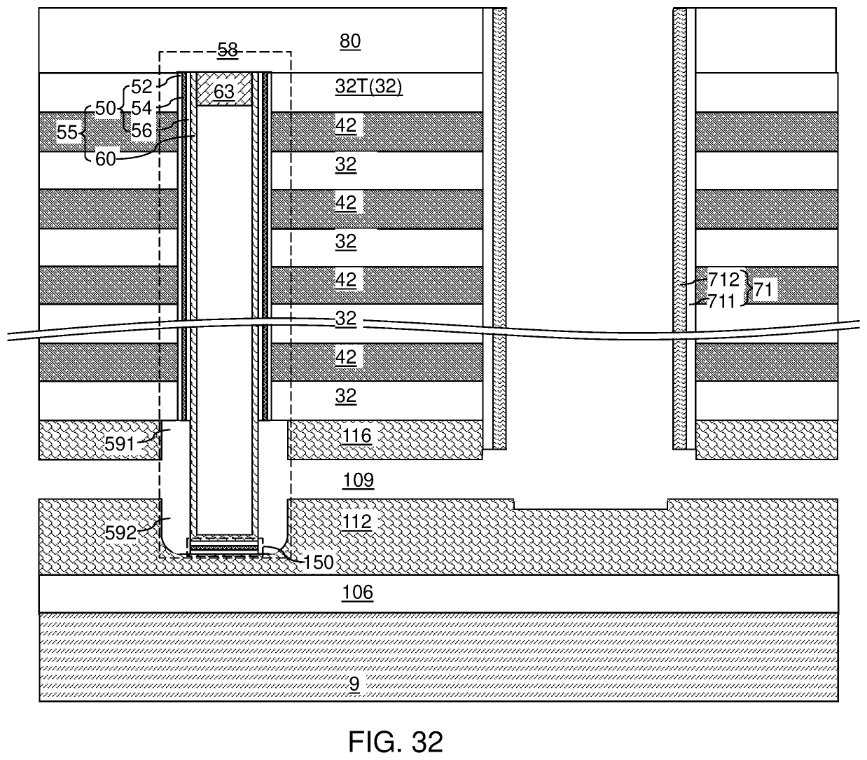

Referring to FIG. 32, the upper sacrificial liner 105 and the lower sacrificial liner 103 can be removed, for example, by performing an isotropic etch process. The first annular cavity fill structures 511 and the second annular cavity fill structures 512 can be subsequently removed by any suitable method, which may comprise an ashing process that volatilizes the materials of the first annular cavity fill structures 511 and the second annular cavity fill structures 512, or a selective isotropic etch process that etches the materials of the first annular cavity fill structures 511 and the second annular cavity fill structures 512 selective to the materials of the memory films 50 and the source-level semiconductor layers (112, 116).

Subsequently, the processing steps described with reference to FIGS. 15A can be performed. The third exemplary structure may have the same structure as the first exemplary structure illustrated in FIG. 15A after performing the processing steps described with reference to FIG. 15A. The processing steps described with reference to FIGS. 15B-20 can be subsequently performed. The third exemplary structure after performing the processing steps described with reference to FIG. 20 may be the same as the first exemplary structure illustrated in FIG. 20.

Referring to all drawings and according to various embodiments of the present disclosure, a memory device comprises: source-level material layers 110 comprising a stack including a lower source-level semiconductor layer 112, a source contact layer 114, and an upper source-level semiconductor layer 116; an alternating stack (32, 46) of insulating layers 32 and electrically conductive layers 46 located over the source-level material layers 110; a memory opening 49 vertically extending through the alternating stack (32, 46) and into an upper portion of the source-level material layers 110; and a memory opening fill structure 58 located in the memory opening 49 and comprising a memory film 50 and a vertical semiconductor channel 60. The source contact layer 114 comprises a horizontally-extending portion 114H and a vertically-extending portion 114V having a greater vertical extent than the horizontally-extending portion 114H, having an inner cylindrical sidewall contacting a bottom portion of the vertical semiconductor channel 60, and contacting a bottommost insulating layer 32B within the alternating stack (32, 46), as shown in FIG. 15H.

In one embodiment, a contact area between the vertically-extending portion 114V of the source contact layer 114 and the bottommost insulating layer 32B comprises a planar annular surface PAS; and an outer periphery of the planar annular surface PAS is laterally offset from an inner periphery of the annular shape by a uniform lateral offset distance. In one embodiment, the vertically-extending portion 114V of the source contact layer 114 comprises an upper cylindrical sidewall UCS that overlies the horizontally-extending portion and a lower cylindrical sidewall LCS that underlies the horizontally-extending portion.

In one embodiment, an upper periphery of the upper cylindrical sidewall UCS coincides with the outer periphery of the planar annular surface PAS. In one embodiment, the upper cylindrical sidewall UCS and the lower cylindrical sidewall LCS are vertically coincident. In one embodiment, the vertically-extending portion 114V of the source contact layer 114 comprises a vertically-convex tapered sidewall VCTS that is adjoined to a bottom periphery of the lower cylindrical sidewall LCS such that a lateral extent of the vertically-extending portion decreases with a downward distance from the alternating stack (32, 46) below a horizontal plane including the bottom periphery of the lower cylindrical sidewall LCS.

In one embodiment, a top surface of the vertically-extending portion 114V of the source contact layer 114 contacts a bottom surface of the memory film 50 at or above a horizontal plane including a bottom surface of the bottommost insulating layer 32B. In one embodiment, an outer cylindrical sidewall of the vertically-extending portion 114V of the source contact layer 114 is laterally offset from the vertical semiconductor channel 60 by a lateral offset distance that is greater than a thickness of the memory film 50.

In one embodiment, the source-level material layers 110 also comprise a source-level insulating fill material layer 115 that is embedded within the source contact layer 114. In one embodiment, the source contact layer 114 has a thickness that is less than one half of a lateral spacing between the vertical semiconductor channel 60 and the upper source-level semiconductor layer 116.

In one embodiment, the memory opening fill structure 58 also comprises a dielectric layer stack 150 underlying a bottom surface of the vertical semiconductor channel 60 and having a same set of materials as the memory film 50; and the dielectric layer stack 150 contacts the lower source-level semiconductor layer 112 and the source contact layer 114. In one embodiment, the vertical semiconductor channel 60 has a doping of a first conductivity type; the lower source-level semiconductor layer 112, and the upper source-level semiconductor layer 116 have a doping of a second conductivity type that is an opposite of the first conductivity type; and the source contact layer comprises a semiconductor layer having a doping of the second conductivity type.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein. each of such documents is incorporated herein by reference in their entirety.

What is claimed is:

1. A memory device, comprising:
source-level material layers comprising a stack including a lower source-level semiconductor layer, a source contact layer, and an upper source-level semiconductor layer;
an alternating stack of insulating layers and electrically conductive layers located over the source-level material layers;
a memory opening vertically extending through the alternating stack and into an upper portion of the source-level material layers; and
a memory opening fill structure located in the memory opening and comprising a memory film and a vertical semiconductor channel,
wherein the source contact layer comprises a horizontally-extending portion and a vertically-extending portion having a greater vertical extent than the horizontally-extending portion, having an inner cylindrical sidewall contacting a bottom portion of the vertical semiconductor channel, and contacting a bottommost insulating layer within the alternating stack.

2. The memory device of claim 1, wherein:
a contact area between the vertically-extending portion of the source contact layer and the bottommost insulating layer comprises a planar annular surface; and
an outer periphery of the planar annular surface is laterally offset from an inner periphery of the annular shape by a uniform lateral offset distance.

3. The memory device of claim 2, wherein the vertically-extending portion of the source contact layer comprises an upper cylindrical sidewall that overlies the horizontally-extending portion and a lower cylindrical sidewall that underlies the horizontally-extending portion.

4. The memory device of claim 3, wherein an upper periphery of the upper cylindrical sidewall coincides with the outer periphery of the planar annular surface.

5. The memory device of claim 3, wherein the upper cylindrical sidewall and the lower cylindrical sidewall are vertically coincident.

6. The memory device of claim 3, wherein the vertically-extending portion of the source contact layer comprises a vertically-convex tapered sidewall that is adjoined to a bottom periphery of the lower cylindrical sidewall such that a lateral extent of the vertically-extending portion decreases with a downward distance from the alternating stack below a horizontal plane including the bottom periphery of the lower cylindrical sidewall.

7. The memory device of claim 1, wherein a top surface of the vertically-extending portion of the source contact layer contacts a bottom surface of the memory film at or above a horizontal plane including a bottom surface of the bottommost insulating layer.

8. The memory device of claim 1, wherein an outer cylindrical sidewall of the vertically-extending portion of the source contact layer is laterally offset from the vertical semiconductor channel by a lateral offset distance that is greater than a thickness of the memory film.

9. The memory device of claim 1, wherein the source-level material layers further comprise a source-level insulating fill material layer that is embedded within the source contact layer.

10. The memory device of claim 1, wherein the source contact layer has a thickness that is less than one half of a lateral spacing between the vertical semiconductor channel and the upper source-level semiconductor layer.

11. The memory device of claim 1, wherein:
the memory opening fill structure further comprises a dielectric layer stack underlying a bottom surface of the vertical semiconductor channel and having a same set of materials as the memory film; and
the dielectric layer stack contacts the lower source-level semiconductor layer and the source contact layer.

12. The memory device of claim 1, wherein:
the vertical semiconductor channel has a doping of a first conductivity type; and
the lower source-level semiconductor layer and the upper source-level semiconductor layer have a doping of a second conductivity type that is an opposite of the first conductivity type; and
the source contact layer comprises a semiconductor layer having a doping of the second conductivity type.

13. A method of forming a memory device, comprising:
forming in-process source-level material layers comprising a stack including a lower source-level semiconductor layer, a source-level sacrificial layer, and an upper source-level semiconductor layer;
forming an alternating stack of insulating layers and sacrificial material layers located over the in-process source-level material layers;
forming a memory opening vertically extending through the alternating stack and an upper portion of the in-process source-level material layers, wherein the memory opening comprises a first annular cavity located at a level of the upper source-level semiconductor layer and undercutting the alternating stack;
forming a first annular cavity fill structure in the first annular cavity;
forming a memory opening fill structure in a volume of the memory opening other than a volume of the first annular cavity, wherein the memory opening fill structure comprises a memory film and a vertical semiconductor channel;
replacing at least the source-level sacrificial layer and the first annular cavity fill structure with at least one replacement material layer comprising a source contact layer, wherein the source contact layer is formed directly on a lower portion of an outer sidewall of the vertical semiconductor channel; and
replacing the sacrificial material layers with electrically conductive layers.

14. The method of claim 13, wherein:
the memory film comprises a blocking dielectric layer, a memory material layer, and a tunneling dielectric layer; and
the first annular cavity fill structure is removed after formation of the blocking dielectric layer.

15. The method of claim 14, wherein the first annular cavity fill structure is removed prior to formation of the memory material layer.

16. The method of claim 15, wherein:
the first annular cavity fill structure comprises a carbon-based material; and
the first annular cavity fill structure is removed by annealing the first annular cavity fill structure above its decomposition temperature to decompose the carbon-based material into a gas which diffuses through the blocking dielectric layer into the memory opening.

17. The method of claim 13, wherein the first annular cavity is formed by performing a selective isotropic etch process that etches a semiconductor material of the upper source-level semiconductor layer selective to a material of the source-level sacrificial layer.

18. The method of claim 13, further comprising:
forming a second annular cavity by laterally recessing the lower source-level semiconductor layer; and
forming a second annular cavity fill structure in the second annular cavity, wherein:
the memory film is formed outside a volume of the second annular cavity; and
a portion of source contact layer is formed in the volume of the second annular cavity.

19. The method of claim 13, wherein the step of forming the memory opening comprises:
forming a cylindrical cavity through the alternating stack and the upper portion of the in-process source-level material layers; and
isotropically recessing the upper source-level semiconductor layer and the lower source-level semiconductor layer selective to materials of the alternating stack.

20. The method of claim 13, wherein the step of forming the memory opening comprises:
forming a sacrificial pedestal structure in the upper portion of the in-process source-level material layers prior to formation of the alternating stack;
forming a cylindrical cavity through the alternating stack such that a top surface of the sacrificial pedestal structure is exposed underneath the cylindrical cavity; and
removing the sacrificial pedestal structure from underneath the cylindrical cavity, wherein the memory opening comprises a combination of the cylindrical cavity and a void formed by removal of the sacrificial pedestal structure.
